(19) United States
(12) Patent Application Publication
(10) Pub. No.: US 2026/0223460 A1
(43) Pub. Date: Jul. 30, 2026

(54) INTEGRATED CIRCUIT DEVICE WITH VARIED CONDUCTOR ARRANGEMENT, AND METHOD OF GENERATING A LAYOUT USING THE SAME

(71) Applicant: TAIWAN SEMICONDUCTOR MANUFACTURING COMPANY, LTD., Hsinchu (TW)

(72) Inventors: Hui-Zhong ZHUANG, Hsinchu (TW); Hung-Li CHIANG, Hsinchu (TW); Kuan Yu CHEN, Hsinchu (TW); Wei-Cheng LIN, Hsinchu (TW); Jiann-Tyng TZENG, Hsinchu (TW)

(21) Appl. No.: 19/212,941

(22) Filed: May 20, 2025

Related U.S. Application Data
(60) Provisional application No. 63/749,150, filed on Jan. 24, 2025.

(51) Int. Cl. H10D 89/10; H10D 84/90

(52) U.S. Cl. CPC H10D 89/10; H10D 84/981

(57) ABSTRACT

An integrated circuit device includes a first and second insulating structures spaced apart in a first direction and extending in a second direction; a first conductive segment on a first peripheral track of a first conductive layer; a second conductive segment on a second track of the first conductive layer; a first gap in the first conductive layer at an end of the first conductive segment; a second gap in the first conductive layer at an end of the second conductive segment; and a gate structure between the first insulating structure and the second insulating structure, adjacent the second gap. The second gap is between the first gap and the gate structure. The first insulating structure is between the first gap and the gate structure. The first conductive segment extends away from the gate structure to protrude beyond the second gap.

### PRIORITY

This application claims the benefit of U.S. Provisional Application No. 63/749,150, filed Jan. 24, 2025, which is herein incorporated by reference in its entirety.

### BACKGROUND

Integrated circuit devices are fabricated with increasing density and complexity as integrated circuit technology advances. Standard cells are often used to simplify integrated circuit design.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a layout diagram of an integrated circuit according to some embodiments.

FIG. 2 is a layout diagram of an integrated circuit according to some embodiments.

FIG. 3 is a layout diagram of an integrated circuit according to some embodiments.

FIG. 4 is a layout diagram of an integrated circuit according to some embodiments.

FIG. 5 is a layout diagram of an integrated circuit according to some embodiments.

FIG. 6 is a layout diagram of an integrated circuit according to some embodiments.

FIG. 7 is a layout diagram of an integrated circuit according to some embodiments.

FIG. 8 is a flowchart of a method of manufacturing an IC device according to some embodiments.

FIG. 9 is a flowchart of a method of generating a layout according to some embodiments.

FIG. 10A is a schematic diagram of a method of generating a layout according to some embodiments.

FIG. 10B is a flowchart of a method of fabricating an integrated circuit device according to some embodiments.

FIG. 11 is a block diagram of an IC device design system according to some embodiments.

FIG. 12 is a block diagram of an IC manufacturing system, and an IC manufacturing flow associated therewith, according to some embodiments.

### DETAILED DESCRIPTION

The following disclosure provides many different embodiments, or examples, for implementing different features of the provided subject matter. Specific examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an integrated circuit design has standard cells with boundary-M0 protrusions and/or recesses that allow for cut-metal-zero (cut-M0 or CM0) patterns to be placed in a relatively greater number of positions along a standard cell edge, relative to another approach in which the boundary-M0 protrusions and/or recesses are not provided.

In some embodiments, an integrated circuit design includes vias, e.g., vias for gates or sources/drain regions (S/D regions), that are positioned in a zigzag arrangement in a row-extending direction of a layout. Corresponding cut-gate patterns (CPO patterns) and cut-MD patterns (CMD patterns) are also placed in a zigzag arrangement in the row-extending direction. The zigzag arrangement allows for an increased width (in a cell-height direction) of the CPO and/or CMD patterns.

Meanwhile, the progressive scaling (i.e., shrinkage) of integrated circuit devices poses challenges for lithographic techniques. An example of such challenges arises when an integrated circuit device layout has one or more cut-M0 patterns (CM0 patterns) in an edge region of a cell or cells in a first row that are near to, but offset from, one or more CM0 patterns in an edge region of an adjoining cell or cells in a second row that adjoins the first row. The CM0 pattern(s) in the cell(s) of the first row and the CM0 pattern(s) in the cells(s) of the adjoining second row can combine to form pattern shapes with an offset, e.g., an offset of 0.5 CPP, that pose a lithographic challenge, e.g., when forming patterns using a self-aligned double-patterning process.

For example, for a first row that extends over a second row, a first CM0 pattern in a lower region of a first cell in the first row and a second CM0 pattern in an upper region of a second cell in the second row that are offset relative to each other by 0.5 CPP can form an overall shape that can be described as stepped, staircase, or lightning-shaped. Such a shape may not be accurately reproduced during device manufacture and, thus, may be undesirable in a device layout. Thus, a layout rule may limit, e.g., foreclose, arrangements of standard cells that result in such a shape.

As another example, for a first row that extends over a second row, a first CM0 pattern in a lower region of a first cell in the first row and second and third CM0 patterns in upper regions of second and third cells in the second row that are offset relative to, and bracket, the first CM0 pattern by 0.5 CPP can form an overall shape that can be described as a right-side-up or up-side-down Y shape or a tuning fork or inverted tuning fork shape, and can be viewed as two mirror-image lightning-shaped patterns in which overlap in part. Such a shape may not be accurately reproduced during device manufacture and, thus, may be undesirable in a device layout. Thus, a layout rule may limit, e.g., foreclose, arrangements of standard cells that result in such a shape.

In an integrated circuit device in which the zigzag arrangement and the lithographic patterning rules are both at play, a situation can arise in which possible positions for CM0 patterns in an upper and/or lower region of a cell, e.g., in an M0 track adjacent to a vertical cell boundary, are limited. This can have an effect of limiting design options for circuit pins in an M0 conductive layer, e.g., input pins, output pins, and the like. One possible result is having a pin that is longer than desired, which can result in an increased pin capacitance relative to a shorter pin. Another possible result is having few options for pin placement.

In some embodiments, a standard cell includes an M0 protrusion and/or recess, which enables placement of a CM0 pattern (and a corresponding M0 gap that is formed by cutting an M0 conductor according to the CM0 pattern) with greater flexibility as compared to a standard cell without the M0 protrusion and/or recess.

Herein, references to a standard cell are synonymous with references to a cell. Further, a row-extending direction of standard cells in a layout corresponds to a first direction herein. The first direction (X-axis direction) is parallel to the X axis in the figures and encompasses both left-to-right and right-to-left directions. A row-height direction corresponds to a second direction herein. The second direction (Y-axis direction) is parallel to the Y axis in the figures and encompasses both top-to-bottom and bottom-to-top directions. Although the X and Y axes are generally assumed to be orthogonal to each other, some designs may be implemented using axes that are non-orthogonal. A pitch of cell features is referred to as CPP herein, which may also be referred to as contacted poly pitch, and refers to a pitch, e.g., a center-to-center spacing or its equivalent, of gate patterns or gate structures. In some embodiments, the gate structures are, or include, polysilicon (poly) but gate structures are formed without polysilicon in some embodiments, e.g., the gate structures use a metal or other conductor; references to CPP encompass gate structures formed without polysilicon. In general, a gate or poly level in a layout is directly over the active area or active region, and diffusion contact structures, e.g., metal-on-diffusion or MD structures, are interleaved with the gate structures and generally extend in a same direction as the gate structures.

Also herein, a first conductive layer over the gate structures and MD structures is referred to as an M0 layer or first metal layer; however, conductors other than metals, e.g., a doped semiconductor or the like, are encompassed by references to the M0 layer and first metal layer. In an example method of fabricating an integrated circuit, a regular metal pattern is formed, e.g., a base level metal interconnect pattern (M0 layer), and then portions of the metal pattern are selectively cut (removed) according to cut-M0 patterns (CM0 patterns) of the applicable design. The CM0 patterns thus define discontinuities or gaps in the M0 layer or M0 conductors (i.e., define M0 discontinuities or M0 gaps). An insulating material, e.g., a dielectric isolation material, is filled in the portions where the M0 layer or M0 conductors lines are removed in the metal cut process. Thus, the insulating material generally has the shape of the CM0 pattern. The insulating material that is formed where an M0 conductor is cut by the CM0 pattern can be considered a replacement M0 insulator or structure. A CM0 pattern in a layout and the corresponding CM0 gap (or corresponding replacement M0 insulator) in a device completely separate one portion of an M0 pattern or structure from an adjacent portion of the M0 pattern or structure; it is assumed that the CM0 pattern or corresponding replacement insulator does not cut layers above or below M0, unless stated otherwise. An M0 pattern in a layout and an M0 conductor or conductive segment in the M0 layer generally extend in the first direction, i.e., parallel to the X axis. The CM0 pattern in a layout (and the corresponding M0 gap formed thereby in the device) generally extends in the second direction, i.e., parallel to the Y axis.

Also herein, an M0 pattern in a layout and an M0 conductor or conductive segment in a device are described as extending along an M0 track (the M0 pattern follows or is placed on the M0 track and is used to form the M0 structure, i.e., the M0 conductor or M0 conductive segment). In advanced process nodes, M0 conductors in adjacent M0 tracks may be fabricated in different operations, e.g., every other M0 track may be fabricated in a first operation, and tracks interleaved therewith may be fabricated in a second operation. Although the M0 tracks may thus be designated with different names, patterns, or the like, the order of fabrication of the M0 tracks may be reversed or all the M0 tracks may be fabricated together in various embodiments. An M0 track closest to a cell edge among a plurality of M0 tracks in the cell may be referred to as a peripheral M0 track, or an uppermost or lowermost M0 track in the cell. A peripheral M0 track is adjacent to a cell edge and has no other M0 tracks between it and the cell edge. Embodiments described herein include power rails, e.g., to provide VDD or VSS, formed in the M0 layer; such power rails are not considered to be an M0 track or on an M0 track, even though formed in the M0 layer. In the figures, embodiments are described in which cells have five M0 tracks between power rails; such cells, and any cells having a plurality of M0 tracks, have exactly two “peripheral” M0 tracks, which may be distinguished therebetween by references to an “upper” or first peripheral M0 track and a “lower” or second peripheral M0 track. The peripheral M0 tracks are closest to the horizontal cell boundaries (i.e., the cell boundaries that extend in the first direction) and closest to the power rails, among the M0 tracks in the cell. It will be understood that the terms “upper” and “lower” are merely for the sake of description; embodiments also encompass cells that are inverted with reference to the examples described herein. Further, the use of five M0 tracks is merely for the sake of explanation and greater than five tracks or fewer than five tracks are used in other embodiments, including even and odd numbers of tracks. Likewise, embodiments are described in which cells have 5 CPP and 3 CPP widths, merely by way of example; however, embodiments encompass cells with widths other than 5 CPP and 3 CPP, including even and odd numbers of gates.

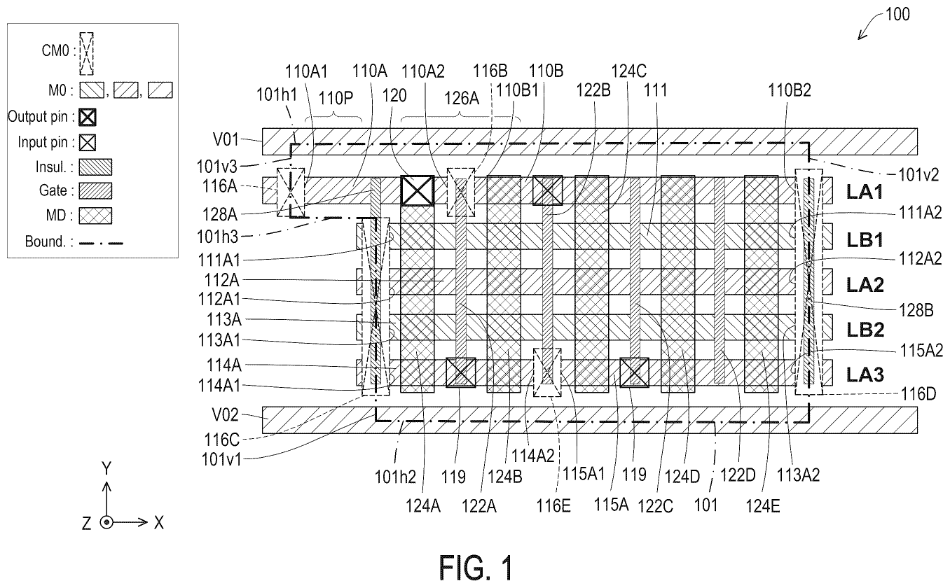

FIG. 1 is a layout diagram of an integrated circuit 100 according to some embodiments.

The layout diagram of FIG. 1 is representative of a portion of an integrated circuit device, e.g., a semiconductor device. Structures in the device are represented by patterns (also referred to as shapes) in the layout diagram. Patterns illustrated in FIG. 1 are used to fabricate structures of an integrated circuit device according to some embodiments. For simplicity of discussion, elements in the layout diagram of FIG. 1 (and also in other layout diagrams disclosed herein) may be referred to as if they are structures rather than patterns per se. The following description applies to both the integrated circuit layout and the corresponding device.

In the integrated circuit 100, a boundary of a standard cell 101 is denoted by a dot-dash line. A first power rail V01 and a second power rail V02 are spaced apart in the second direction and provide power for the cell 101. In some embodiments, the first power rail V01 is configured to supply a first power voltage, e.g., one of VSS or VDD, and the second power rail V02 is configured to supply a second power voltage, e.g., the other of VSS or VDD. The first and second power rails V01 and V02 are in a first conductive layer, denoted as M0. The M0 layer is a conductive layer closest to the substrate and over a gate layer (or poly layer), although the present disclosure is also applicable in other embodiments to backside conductive layers, e.g., a BMO layer, a backside power rail, a super power rail, a backside power delivery network, or the like.

The integrated circuit 100 includes five M0 tracks (denoted, from top to bottom in FIG. 1, as LA1, LB1, LA2, LB2, and LA3) between the first and second power rails V01 and V02. The M0 tracks are where M0 conductors (also referred to as conductive segments) are fabricated in the M0 layer. M0 tracks LA1 and LA3, being closest to the power rails, are referred to as peripheral M0 tracks. The peripheral M0 track LA1 may be referred to as a first peripheral M0 track and the peripheral M0 track LA3 may be referred to as a second peripheral M0 track.

The M0 conductors couple, among other things, gate structures 122A, 122B, 122C, and 122D (collectively, gate structures 122), and MD structures 124A, 124B, 124C, 124D, and 124E (collectively, MD structures 124) that are interleaved with the gate structures 122 and overlap corresponding S/D regions in the active regions. The gate structures 122 and the MD structures 124 extend in the second direction between the M0 layer and the substrate. A gate structure 122 and corresponding MD structures 124 on either side thereof are combined to form one or more transistors in the cell 101, e.g., a transistor 126A. In FIG. 1, the M0 conductors include, among other things, conductive segments for three input pins 119 (VG pins) and one output pin 120 (VD pin).

The gate structures 122A cross active regions (not shown in FIG. 1) that extend in the first direction. Active regions of one cell are isolated from active regions of an adjacent cell in a same row by active region interruptions. The active region interruptions are functional and/or structural interruptions of the active regions in various embodiments. An example of a functional interruption of the active region is a dummy gate structure (which is not part of a functional transistor) configured to receive a voltage that inhibits conduction in an underlying portion of the corresponding active region, e.g., inhibits an inversion layer in the underlying portion of the corresponding active region. Examples of a structural interruption in the active region include a physical edge of the active region or a gap in the active region, a doping or diffusion region in the active region that interrupts conductivity of a first portion of the active region from a second portion of the active region, an insulating structure transecting the active region, and the like. In the integrated circuit 100, it is assumed that the active region interruptions are insulating structures, examples of which include a continuous oxide diffusion (CNOD) structure, a poly over diffusion edge (PODE) structure, a continuous poly over diffusion edge (CPODE) structure, an isolation dummy gate, and the like. However, other active region interruptions are used in other embodiments. In the integrated circuit 100, active region interruptions are formed by a first insulating structure 128A and a second insulating structure 128B, which extend in the second direction. All of the gate structures 122 and the MD structures 124 of the cell 101 are arranged between the first insulating structure 128A and the second insulating structure 128B. The first and second insulating structures 128A and 128B, the gate structures 122, and the MD structures 124 are between a substrate and a first conductive layer (M0 layer) along (or relative to) a third direction (Z-axis direction).

In general, M0 conductors are formed to extend along the M0 tracks, and cut-M0 patterns (CM0 patterns) form cuts (M0 gaps) in the M0 conductors to thus form a plurality of M0 conductive segments extending along the M0 tracks. In FIG. 1, a first CM0 pattern is provided to form a first M0 gap 116A on the first peripheral M0 track LA1. The first M0 gap 116A defines a first end 110A1 of a first M0 conductive segment 110A. A second CM0 pattern is spaced apart from the first CM0 pattern in the first direction to form a second M0 gap 116B on the first peripheral M0 track LA1. The second M0 gap 116B defines a second end 110A2 of the first M0 conductive segment 110A. A third CM0 pattern extends in the second direction overlying (i.e., vertically overlapping) a portion of the first insulating structure 128A to form a third M0 gap 116C. The first M0 gap 116A is offset in the first direction, away from the center of the cell 101, relative to the third M0 gap 116C. A fourth CM0 pattern is spaced apart from the third CM0 pattern in the first direction to form a fourth M0 gap 116D.

A first horizontal boundary 101h1 of the cell 101 corresponds to the first power rail V01, e.g., to a middle of the first power rail V01 relative to the second direction (Y-axis direction). A second horizontal boundary 101h2 of the cell 101 is spaced apart in the second direction from the first horizontal boundary 101h1 and corresponds to the second power rail V02, e.g., to a middle of the second power rail V02 relative to the second direction. In the example cell of FIG. 1, the first horizontal boundary 101h1 is longer than the second horizontal boundary 101h2.

A first vertical boundary 101v1 of the cell 101 corresponds to the first insulating structure 128A, e.g., to a middle of the first insulating structure 128A relative to the first direction. The first vertical boundary 101v1 corresponds to a portion of the first insulating structure 128A that is overlapped by the second through fifth M0 tracks LB1, LA2, LB2, and LA3. A second vertical boundary 101v2 of the cell 101 is spaced apart from the first vertical boundary 101v1 and corresponds to the second insulating structure 128B, e.g., to a middle of the second insulating structure 128B relative to the first direction.

A third vertical boundary 101v3 corresponds to the first M0 gap 116A, e.g., to a middle of the first M0 gap relative to the first direction. The third vertical boundary 101v3 is offset in the first direction relative to the first vertical boundary 101v1 such that the cell 101 has a protrusion, namely the first M0 conductive segment 110A on the first peripheral M0 track LA1 has a protruding portion 110P that protrudes or extends beyond the first vertical boundary 101v1 at the protrusion of the cell 101. A third horizontal boundary 101h3 connects a lower end of the third vertical boundary 101v3 to an upper end of the first vertical boundary 101v1. The M0 gaps 116A, 116C, and 116D that overlap the vertical boundaries may be referred to as boundary metal cut regions, which disconnect the cell 101 from horizontally-adjacent standard cells.

The first M0 gap 116A cuts the first M0 conductive segment 110A on the first peripheral track LA1 at the end of the protruding portion 110P. The second M0 gap 116B also cuts the M0 conductor on the first peripheral track LA1, such that the first M0 conductive segment 110A is formed on the first peripheral M0 track LA1 between the first and second M0 gaps 116A and 116B. A via structure couples the first M0 conductive segment 110A of VD pin 120 to an MD structure 124A. The first M0 conductive segment 110A extends in the first direction, away from the center of the cell 101, beyond the first vertical boundary 101v1.

In FIG. 1, a second conductive segment 110B extends from the second M0 gap 116B to the fourth M0 gap 116D, with a first end 110B1 of the second conductive segment 110B at the second M0 gap 116B and a second end 110B2 of the second conductive segment at the fourth M0 gap. In other embodiments, a plurality of conductive segments is provided between the second M0 gap 116B and the fourth M0 gap 116D, e.g., by forming one or more additional M0 gaps along the first peripheral M0 track LA1. A third conductive segment 111A has a first end 111A1 at the third M0 gap 116C and a second end 111A2 at the fourth M0 gap 116D. A fourth conductive segment 112A has a first end 112A1 at the third M0 gap 116C and a second end 112A2 at the fourth M0 gap 116D. A fifth conductive segment 113A has a first end 113A1 at the third M0 gap 116C and a second end 113A2 at the fourth M0 gap 116D. A sixth conductive segment 114A has a first end 114A1 at the third M0 gap 116C and a second end 114A2 at a fifth M0 gap 116E. A seventh conductive segment 115A has a first end 115A1 at the fifth M0 gap 116E and a second end 115A2 at the fourth M0 gap 116D. The sixth and seventh conductive segments 114A and 115A extend along the second peripheral M0 track LA3.

In FIG. 1, various conductive segments and corresponding M0 gaps are shown. In other embodiments, the more or fewer conductive segments and M0 gaps are formed. For example, the third, fourth, and fifth conductive segments 111A, 112A, and 113A are further segmented by additional M0 gaps in other embodiments. Further, the second M0 gap 116B and the fifth M0 gap 116E are located in other positions along the peripheral M0 tracks LA1 and LA2 in other embodiments. Further, one or more VG pins 319 and/or VD pins 120 are located in other positions in the cell 101 and/or are provided in different numbers or omitted in other embodiments. Further, although FIG. 1 shows each of the MD structures 124 as being the same, in other embodiments the MD structures 124 have different lengths and/or are positioned differently, e.g., by cut-MD structures arranged in a staggered or zigzag arrangement for each MD structure.

In another approach in which a standard cell is purely rectangular (and thus has no protrusion), placement of cuts, e.g., M0 gaps, in peripheral regions of the cell is limited by via arrangements and/or the need to avoid forming shapes that may not be accurately reproduced during device manufacture, e.g., lightning shapes, tuning fork shapes or inverted tuning fork shapes, and the like. For example, in another approach, a CM0 pattern cannot be placed in the position of the second CM0 pattern (116B) in FIG. 1 because such a CM0 pattern would be too close to a vertical cell boundary, e.g., within 1.5 CPP of the vertical cell boundary.

On the other hand, in the cell 101 in FIG. 1, the first M0 gap 116A is shifted outward in the first direction (i.e., away from the center of the cell 101) and thus the second M0 gap 116B is not within 1.5 CPP of the third vertical boundary 101v3. The cell 101 thus provides greater flexibility, relative to the other approach, in segmenting the peripheral M0 conductors such that greater variations are possible in the lengths of the peripheral M0 conductive segments and greater flexibility is provided in routing. This will be further explained below.

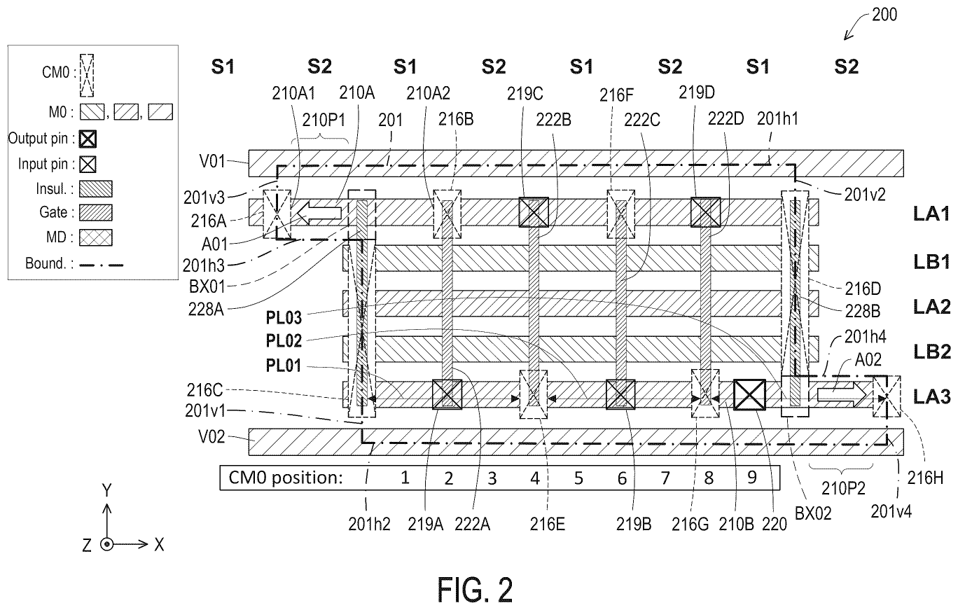

FIG. 2 is a layout diagram of an integrated circuit 200 according to some embodiments.

In FIG. 2, the integrated circuit 200 is similar to the integrated circuit 100 of FIG. 1. Elements in FIG. 2 generally correspond to elements in FIG. 1 with numbers incremented by 100.

In FIG. 2, a standard cell 201 includes protruding portions on both peripheral M0 tracks LA1 and LA3, the protruding portions extending in the first direction away from the center of the cell 201. M0 conductive segments in the protruding portions are bounded by M0 gaps that are moved outward relative to another approach in which a standard cell is purely rectangular.

In the integrated circuit 200, a boundary of the cell 201 is denoted by a dot-dash line. A first power rail V01 and a second power rail V02 are spaced apart in the second direction and provide power for the cell 201. In some embodiments, the first power rail V01 is configured to supply a first power voltage, e.g., one of VSS or VDD, and the second power rail V02 is configured to supply a second power voltage, e.g., the other of VSS or VDD. The first and second power rails V01 and V02 are in the first conductive layer, M0. The M0 layer is a conductive layer closest to the substrate and over a gate layer (or poly layer), although the present disclosure is also applicable to backside conductive layers in other embodiments.

The integrated circuit 200 includes five M0 tracks (denoted, from top to bottom in FIG. 2, as LA1, LB1, LA2, LB2, and LA3) between the first and second power rails V01 and V02. The peripheral M0 track LA1 may be referred to as a first peripheral M0 track and the peripheral M0 track LA3 may be referred to as a second peripheral M0 track.

The M0 conductors couple, among other things, four gate structures 222A, 222B, 222C, and 222D (collectively, gate structures 222). MD structures (not shown in FIG. 2) are interleaved with the gate structures 222 to correspond to source/drain regions S1 and S2. A gate structure 222 and corresponding MD structures on either side thereof are combined to form one or more transistors in the cell 201. In FIG. 2, the M0 conductors include, among other things, conductive segments for first, second, third, and fourth input pins 219A, 219B, 219C, and 219D (collectively, input pins 219) (VG pins) and one output pin 220 (VD pin).

The gate structures 222 cross active regions (not shown in FIG. 2) that extend in the first direction. Active region interruptions are formed by a first insulating structure 228A and a second insulating structure 228B, which extend in the second direction. All of the gate structures 222 and the MD structures of the cell 201 are arranged between the first insulating structure 228A and the second insulating structure 228B. The first and second insulating structures 228A and 228B and the gate structures 222 are arranged at a regular pitch. The cell 201 is equivalent to a 5 CPP cell, i.e., the width of the cell from the first insulating structure to 228A to the second insulating structure 228B is 5 CPP.

The M0 conductors are formed to extend along the M0 tracks, and M0 gaps in the M0 conductors form a plurality of M0 conductive segments extending along the M0 tracks. The cell 201 includes a first M0 gap 216A on the first peripheral M0 track LA1. The first M0 gap 216A defines a first end 210A1 of a first M0 conductive segment 210A.

As indicated by a first arrow A01 and a first dashed box BX01 on the first peripheral M0 track LA1, the first M0 gap 216A corresponds to an upper portion of a third M0 gap 216C that is not formed overlapping the first insulating structure 228A at the first peripheral M0 track LA1 but instead is offset in the first direction, away from the center of the cell 201 by 1 CPP, relative to the third M0 gap 216C. The first M0 conductive segment 210A on the first peripheral M0 track LA1 thus has a first protruding portion 210P1.

A second M0 gap 216B on the first peripheral M0 track LA1 defines a second end 210A2 of the first M0 conductive segment 210A. The third M0 gap 216C vertically overlaps a portion of the first insulating structure 228A. A fourth M0 gap 216D is spaced apart from the third M0 gap 216C in the first direction and vertically overlaps a portion of the second insulating structure 228B. A fifth M0 gap 216E vertically overlaps the second gate structure 222B and cuts the M0 conductor on the second peripheral M0 track LA3. A sixth M0 gap 216F vertically overlaps the third gate structure 222C and cuts the M0 conductor on the first peripheral M0 track LA1. A seventh M0 gap 216G vertically overlaps the fourth gate structure 222D and cuts the M0 conductor on the third peripheral M0 track LA3.

In some embodiments, the insulating structures 228A and 228B have a same first length in the second direction, the M0 gaps 216C and 216D have a same second length in the second direction, and the first length is greater than the second length. In some embodiments, the M0 gaps 216C and 216D partially, but not completely, overlap the corresponding insulating structures 228A and 228B.

As indicated by a second arrow A02 and a second dashed box BX02 on the second peripheral M0 track LA3, an eighth M0 gap 216H corresponds to a lower portion of the fourth M0 gap 216D that is not formed overlapping the second insulating structure 228B at the second peripheral M0 track LA3 but instead is offset in the first direction, away from the center of the cell 201 by 1 CPP, relative to the fourth M0 gap 216D. M0 conductive segment 210B on the second peripheral M0 track LA3 thus has a second protruding portion 210P2.

First input pin 219A (VG pin), which is an M0 conductive segment on the second peripheral M0 track LA3, is bounded by the third M0 gap 216C and the fifth M0 gap 216E, and has a first pin length PL01 of 2 CPP. Second input pin 219B, which is also an M0 conductive segment on the second peripheral M0 track LA3, is bounded by the fifth M0 gap 216E and the seventh M0 gap 216G, and has a second pin length PL02 of 2 CPP. An output pin 220, which is also an M0 conductive segment on the second peripheral M0 track LA3, is bounded by the seventh M0 gap 216G and the eighth M0 gap 216H, and has a third pin length PL03 of 2 CPP.

In FIG. 2, reference positions 1 through 9 for the second peripheral M0 track LA3 are identified below the cell 201. The reference positions 1 through 9 represent possible positions along the second peripheral M0 track LA3 that may be considered for forming M0 gaps. Although some aspects of the following description relate to the placement of CM0 patterns and/or M0 gaps along positions of the second peripheral M0 track LA3, such descriptions also apply to the first peripheral track LA1 in FIG. 2 except for being rotated 180 degrees around a center point of the cell, such that the first and second peripheral M0 tracks have rotational symmetry.

The possible CM0 positions along the peripheral M0 tracks include positions overlapping gate structures and positions overlapping MD structures. In cell 201, there are nine possible CM0 positions along the peripheral M0 tracks: four positions corresponding to the four gate structures and five positions corresponding to MD structures on either side of the gate structures. However, depending on other design features of the integrated circuit, one or more of the possible CM0 positions may be reserved or otherwise undesirable due to device design and/or device manufacturing considerations.

In some embodiments, CMD patterns and CPO patterns are placed in a zigzag arrangement in a row-extending direction, which may also be referred to as a checkerboard arrangement. The zigzag arrangement allows for an increased width (in a cell-height direction) of the CMD and CPO patterns. Accordingly, VD structures and VG structures may be staggered in correspondence with the zigzag arrangement of the CMD and CPO patterns, e.g., to reduce process challenges and simplify fabrication. The staggering can constrain the positions of one or more of VG structures, VD structures, Via0 structures, and M0 pin structures. For example, in some embodiments, the VG position is limited by the zigzag arrangement.

Additionally, when CM0 patterns for cells that are row-adjacent combine to form an overall pattern like a lightning-shaped pattern or a tuning fork or inverted tuning fork-shaped pattern shape, the pattern may not be accurately reproduced during device manufacture and, thus, may be undesirable in a device layout.

In view of the above considerations, some possible positions for the CM0 patterns on the peripheral M0 tracks LA1 and LA3 are not used to implement M0 gaps. Particularly, CM0 positions that are within 1.5 CPP of a vertical cell boundary are not used to form M0 gaps in the peripheral M0 tracks LA1 and LA3. Further, CM0 positions that overlap an MD structure are not used to form M0 gaps in the peripheral M0 tracks LA1 and LA3.

In a 5 CPP cell in another approach in which a standard cell is purely rectangular (and thus has no protrusions), the reference positions 1, 2, 8, and 9 of the second peripheral M0 track LA3 may not be used for CM0 patterns, as being within 1.5 CPP of a vertical cell boundary, and the reference positions 1, 3, 5, 7, and 9 of the second peripheral M0 track LA3 may not be used for CM0 patterns, as overlapping an MD structure (the same is true for the first peripheral M0 track LA1 although the reference positions are numbered from right to left; that is, the first and second peripheral M0 tracks can be viewed as being the same except for being rotated 180 degrees around a center point of the cell, such that the first and second peripheral M0 tracks have rotational symmetry). Thus, in a 5 CPP cell in the other approach, CM0 patterns may be placed only at the reference position 4 and the reference position 6 of the second peripheral M0 track LA3.

In the other approach, the peripheral M0 tracks are thus limited in their utility for input and/or output pins because of the relatively few CM0 positions that are available to form M0 gaps. Additionally, the M0 conductive segments formed on the peripheral M0 tracks may have longer pin lengths than desired, which can lead to undesired increases in capacitance.

In further detail, in the other approach, a CM0 pattern cannot be placed in the position of the second M0 gap 216B in FIG. 2 because such a CM0 pattern would be too close to a vertical cell boundary, e.g., within 1.5 CPP of a vertical cell boundary. Likewise, in the other approach, a CM0 pattern cannot be placed in the position of the pattern for the seventh M0 gap 216G in FIG. 2 because such a CM0 pattern would be too close to a vertical cell boundary, e.g., within 1.5 CPP of a vertical cell boundary.

On the other hand, in the cell 201 according to some embodiments, two additional positions besides reference positions 4 and 6 are available for forming M0 gaps. That is, reference positions 2, 4, 6, and 8 are available.

For example, in the cell 201, a portion of boundary M0 cut on the second peripheral M0 track LA3 is moved outward so that the seventh M0 gap 216G on the reference position 8 is provided to form another M0 conductive segment section with the output pin 220 (VD pin), which has a pin length of 2 CPP. Further, the pin length of the second input pin 219B is decreased to 2 CPP (relative to a pin length of 3 CPP in the absence of the second protruding portion 210P2). These changes along the second peripheral track LA3 are likewise implemented along the first peripheral track LA1.

The cell 201 according to some embodiments thus provides greater flexibility in pin placement and allows for reductions in pin lengths relative to the other approach. Further, the reductions in pin lengths reduce capacitance relative to the other approach.

In FIG. 2, a first horizontal boundary 201h1 of the cell 201 corresponds to the first power rail V01, e.g., to a middle of the first power rail V01 relative to the second direction (Y-axis direction). A second horizontal boundary 201h2 of the cell 201 is spaced apart in the second direction from the first horizontal boundary 201h1 and corresponds to the second power rail V02, e.g., to a middle of the second power rail V02 relative to the second direction. The first horizontal boundary 201h1 and the second horizontal boundary 201h2 have the same length.

A first vertical boundary 201v1 of the cell 201 corresponds to the first insulating structure 228A, e.g., to a middle of the first insulating structure 228A relative to the first direction. The first vertical boundary 201v1 corresponds to a portion of the first insulating structure 228A that is overlapped by the second through fifth M0 tracks LB1, LA2, LB2, and LA3. A second vertical boundary 201v2 of the cell 201 corresponds to the second insulating structure 228B, e.g., to a middle of the second insulating structure 228B relative to the first direction. The second vertical boundary 201v2 corresponds to a portion of the second insulating structure 228B that is overlapped by the first through fourth M0 tracks LA1, LB1, LA2, and LB2. A third vertical boundary 201v3 corresponds to the first M0 gap 216A, e.g., to a middle of the first M0 gap 216A relative to the first direction. The third vertical boundary 201v3 is offset in the first direction relative to the first vertical boundary 201v1 such that the cell 201 has a first protrusion, namely first M0 conductive segment 210A on the first peripheral M0 track LA1 has the first protruding portion 210P1 that protrudes or extends beyond the first vertical boundary 201v1. The first M0 gap 216A cuts the M0 conductor on the first peripheral track LA1 at the end of the first protruding portion 210P1. A third horizontal boundary 201h3 connects a lower end of the third vertical boundary 201v3 to an upper end of the first vertical boundary 201v1. A fourth vertical boundary 201v4 corresponds to the eighth M0 gap 216H, e.g., to a middle of the eighth M0 gap 216H relative to the first direction. The fourth vertical boundary 201v4 is offset in the first direction relative to the second vertical boundary 201v2 such that the cell 201 has a second protrusion, namely the M0 conductive segment 210B on the second peripheral M0 track LA3 has the second protruding portion 210P2 that protrudes or extends beyond the second vertical boundary 201v2. The eighth M0 gap 216H cuts the M0 conductor on the second peripheral track LA3 at the end of the second protruding portion 210P2. A fourth horizontal boundary 201h4 connects an upper end of the fourth vertical boundary 201v4 to a lower end of the second vertical boundary 201v2. The M0 gaps 216A, 216C, 216D, and 216H that overlap the vertical boundaries may be referred to as boundary metal cut regions, which disconnect the cell 201 from horizontally-adjacent standard cells.

In FIG. 2, various conductive segments and corresponding M0 gaps are shown. In other embodiments, the more or fewer conductive segments and M0 gaps are formed. It will be understood that the M0 conductors can be segmented by M0 gaps to provide various intra- and inter-cell routing conductors.

In another approach in which a standard cell is purely rectangular (and thus having no protrusions), placement of cuts, e.g., M0 gaps, in peripheral regions of the cell is limited by the need to avoid forming shapes that may not be accurately reproduced during device manufacture, e.g., lightning shapes, tuning fork shapes or inverted tuning fork shapes, and the like. Thus, in the other approach, a CM0 pattern cannot be placed in the position of the second CM0 pattern (216B) in FIG. 2 because such a CM0 pattern would be too close to a vertical cell boundary, e.g., within 1.5 CPP of the vertical cell boundary. Likewise, in the other approach, a CM0 pattern cannot be placed in the position of the seventh CM0 pattern (216G) in FIG. 2 because such a CM0 pattern would be too close to a vertical cell boundary, e.g., within 1.5 CPP of the vertical cell boundary.

On the other hand, in the cell 201 in FIG. 2, the first M0 gap 216A is shifted outward in the first direction (i.e., away from the center of the cell 201) and thus the second M0 gap 216B is not within 1.5 CPP of the third vertical boundary 201v3. Likewise, the eighth M0 gap 216H is shifted outward in the first direction (i.e., away from the center of the cell 201) and thus the seventh M0 gap 216G is not within 1.5 CPP of the fourth vertical boundary 201v4. The cell 201 thus provides greater flexibility, relative to the other approach, in segmenting the peripheral M0 conductors such that greater variations are possible in the lengths of the peripheral M0 conductive segments and greater flexibility is provided in routing.

In the following description, additional standard cells according to embodiments are described. Some of the standard cells described below are smaller than those described above. Additionally, rather than protrusions at the peripheral M0 tracks, some of the standard cells described below have recesses at the peripheral M0 tracks. Additionally, some of the standard cells described below have both protrusions and recesses at the peripheral M0 tracks. The following Table 1 summarizes the variations in cell size and protrusions and/or recesses.

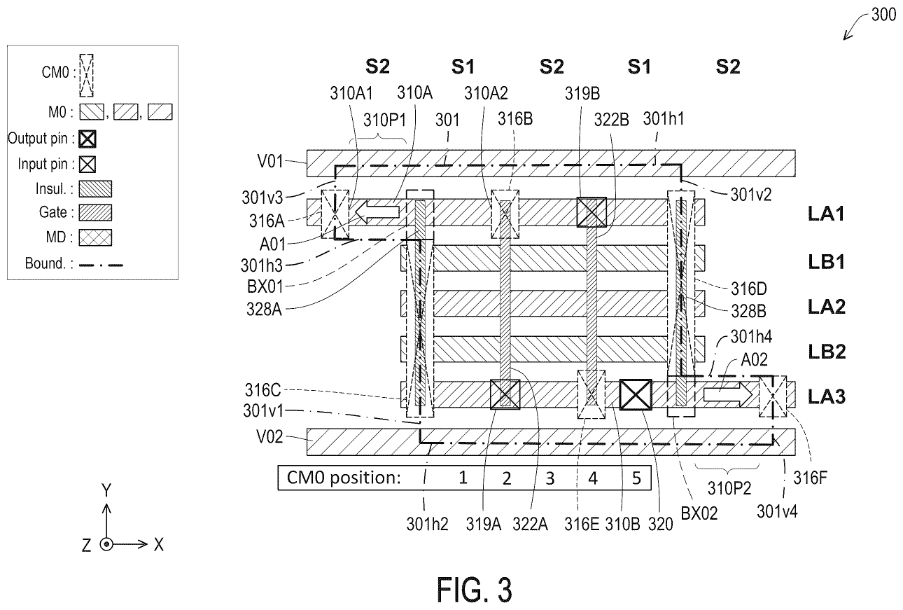

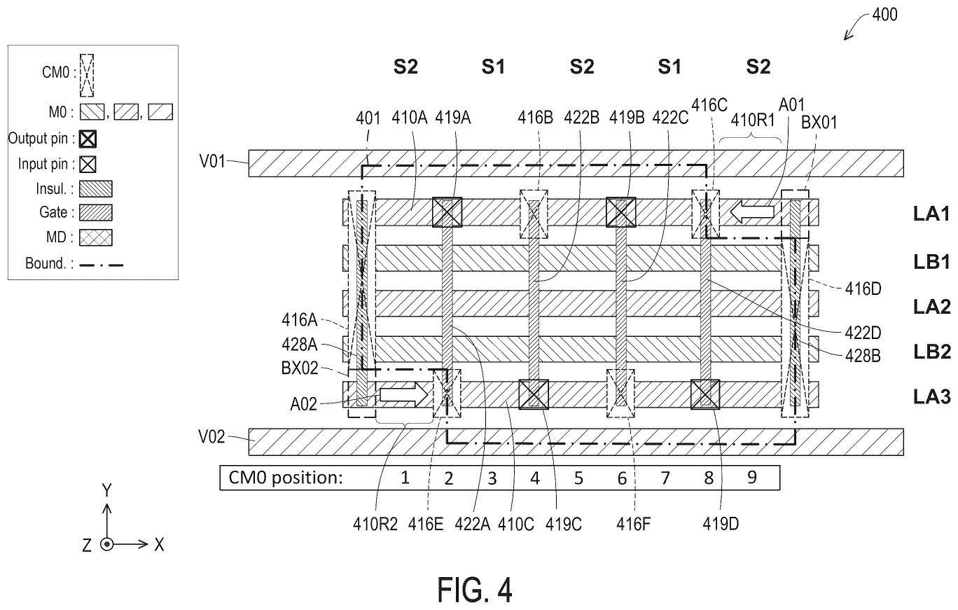

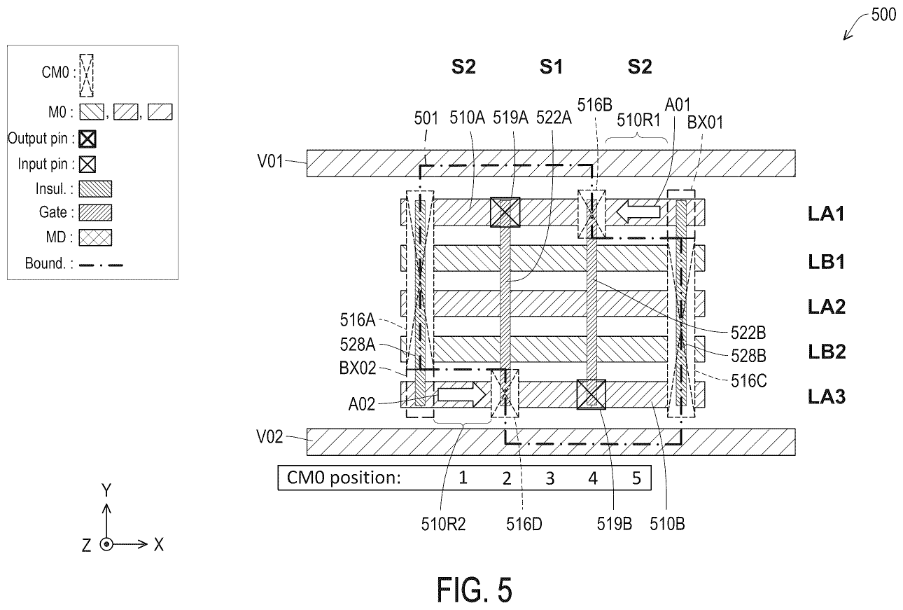

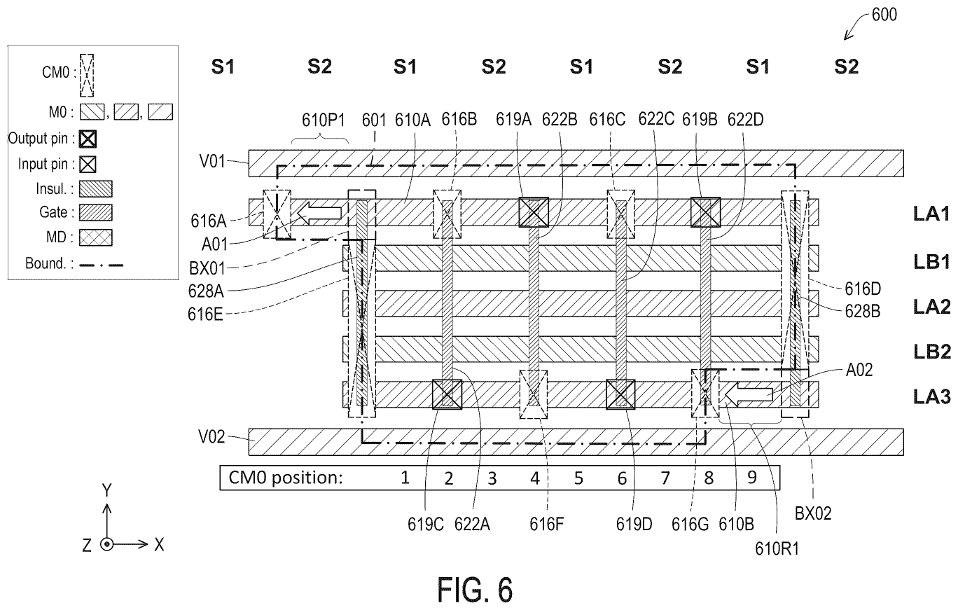

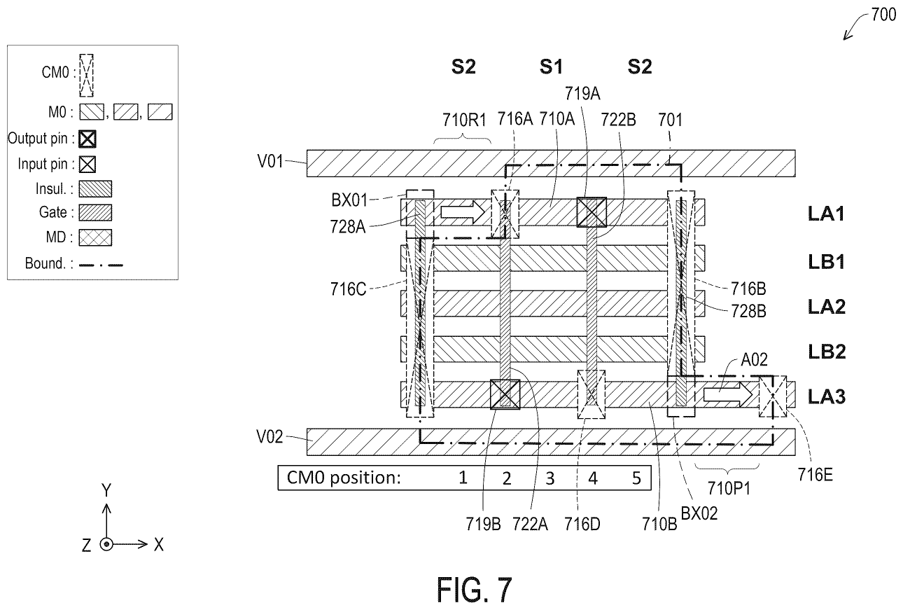

TABLE 1

| | | Upper peripheral | Lower peripheral |
|---|---|---|---|
| | Cell | M0 track: movement | M0 track: movement |
| | CPP | of M0 cut | of M0 cut |
| FIG. 1 | 5 | outward | none |
| FIG. 2 | 5 | outward | outward |
| FIG. 3 | 3 | outward | outward |
| FIG. 4 | 5 | inward | inward |
| FIG. 5 | 3 | inward | inward |
| FIG. 6 | 5 | outward | inward |
| FIG. 7 | 3 | inward | outward |

FIG. 3 is a layout diagram of an integrated circuit 300 according to some embodiments.

In FIG. 3, the integrated circuit 300 is similar to the integrated circuit 100 of FIG. 1. Elements in FIG. 3 generally correspond to elements in FIG. 1 with numbers incremented by 200.

In FIG. 3, a standard cell 301 includes protruding portions on both peripheral M0 tracks LA1 and LA3, the protruding portions extending in the first direction away from the center of the cell 301. M0 conductive segments in the protruding portions are bounded by M0 gaps that are moved outward relative to another approach in which a standard cell is purely rectangular.

In the integrated circuit 300, a boundary of the cell 301 is denoted by a dot-dash line. A first power rail V01 and a second power rail V02 are spaced apart in the second direction and provide power for the cell 301. In some embodiments, the first power rail V01 is configured to supply a first power voltage, e.g., one of VSS or VDD, and the second power rail V02 is configured to supply a second power voltage, e.g., the other of VSS or VDD. The first and second power rails V01 and V02 are in the first conductive layer, M0. The M0 layer is a conductive layer closest to the substrate and over a gate layer (or poly layer), although the present disclosure is also applicable to backside conductive layers in other embodiments.

The integrated circuit 300 includes five M0 tracks (denoted, from top to bottom in FIG. 3, as LA1, LB1, LA2, LB2, and LA3) between the first and second power rails V01 and V02. The peripheral M0 track LA1 may be referred to as a first peripheral M0 track and the peripheral M0 track LA3 may be referred to as a second peripheral M0 track.

The M0 conductors couple, among other things, two gate structures 322A and 322B (collectively, gate structures 322). MD structures (not shown in FIG. 3) are interleaved with the gate structures 322 to correspond to source/drain regions S1 and S2. A gate structure 322 and corresponding MD structures on either side thereof are combined to form one or more transistors in the cell 301. In FIG. 3, the M0 conductors include, among other things, conductive segments for first and second input pins 319A and 319B (collectively, input pins 319) (VG pins) and one output pin 320 (VD pin).

The gate structures 322 cross active regions (not shown in FIG. 3) that extend in the first direction. Active region interruptions are formed by a first insulating structure 328A and a second insulating structure 328B, which extend in the second direction. All of the gate structures 322 and the MD structures of the cell 301 are arranged between the first insulating structure 328A and the second insulating structure 328B. The first and second insulating structures 328A and 328B and the gate structures 322 are arranged at a regular pitch. The cell 301 is equivalent to a 3 CPP cell, i.e., the width of the cell from the first insulating structure to 328A to the second insulating structure 328B is 3 CPP.

The M0 conductors are formed to extend along the M0 tracks, and M0 gaps in the M0 conductors form a plurality of M0 conductive segments extending along the M0 tracks. The cell 301 includes a first M0 gap 316A on the first peripheral M0 track LA1. The first M0 gap 316A defines a first end 310A1 of a first M0 conductive segment 310A.

As indicated by a first arrow A01 and a first dashed box BX01 on the first peripheral M0 track LA1, the first M0 gap 316A corresponds to an upper portion of a third M0 gap 316C that is not formed overlapping the first insulating structure 328A at the first peripheral M0 track LA1 but instead is offset in the first direction, away from the center of the cell 301 by 1 CPP, relative to the third M0 gap 316C. The first M0 conductive segment 310A on the first peripheral M0 track LA1 thus has a first protruding portion 310P1.

A second M0 gap 316B on the first peripheral M0 track LA1 defines a second end 310A2 of the first M0 conductive segment 310A. The third M0 gap 316C vertically overlaps a portion of the first insulating structure 328A. A fourth M0 gap 316D is spaced apart from the third M0 gap 316C in the first direction and vertically overlaps a portion of the second insulating structure 328B. A fifth M0 gap 316E vertically overlaps the second gate structure 322B and cuts the M0 conductor on the second peripheral M0 track LA3.

As indicated by a second arrow A02 and a second dashed box BX02 on the second peripheral M0 track LA3, a sixth M0 gap 316F corresponds to a lower portion of the fourth M0 gap 316D that is not formed overlapping the second insulating structure 328B at the second peripheral M0 track LA3 but instead is offset in the first direction, away from the center of the cell 301 by 1 CPP, relative to the fourth M0 gap 316D. M0 conductive segment 310B on the second peripheral M0 track LA3 thus has a second protruding portion 310P2.

First input pin 319A (VG pin), which is an M0 conductive segment on the second peripheral M0 track LA3, is bounded by the third M0 gap 316C and the fifth M0 gap 316E, and has a first pin length PL01 of 2 CPP. An output pin 320, which is also an M0 conductive segment on the second peripheral M0 track LA3, is bounded by the fifth M0 gap 316E and the sixth M0 gap 316F, and has a pin length of 2 CPP.

In FIG. 3, reference positions 1 through 5 for the second peripheral M0 track LA3 are identified below the cell 301. The reference positions 1 through 5 represent possible positions along the second peripheral M0 track LA3 that may be considered for forming M0 gaps. Although some aspects of the following description relate to the placement of CM0 patterns and/or M0 gaps along positions of the second peripheral M0 track LA3, such descriptions also apply to the first peripheral track LA1 in FIG. 3 except for being rotated 180 degrees around a center point of the cell, such that the first and second peripheral M0 tracks have rotational symmetry.

The possible CM0 positions along the peripheral M0 tracks include positions overlapping gate structures and positions overlapping MD structures. In cell 301, there are five possible CM0 positions along the peripheral M0 tracks: two positions corresponding to the two gate structures and three positions corresponding to MD structures on either side of the gate structures. However, depending on other design features of the integrated circuit, one or more of the possible CM0 positions may be reserved or otherwise undesirable due to device design and/or device manufacturing considerations.

In some embodiments, CMD patterns and CPO patterns are placed in a zigzag arrangement in a row-extending direction, which may also be referred to as a checkerboard arrangement. The zigzag arrangement allows for an increased width (in a cell-height direction) of the CMD and CPO patterns. Accordingly, VD structures and VG structures may be staggered in correspondence with the zigzag arrangement of the CMD and CPO patterns, e.g., to reduce process challenges and simplify fabrication. The staggering can constrain the positions of one or more of VG structures, VD structures, Via0 structures, and M0 pin structures. For example, in some embodiments, the VG position is limited by the zigzag arrangement.

Additionally, when CM0 patterns for cells that are row-adjacent combine to form an overall pattern like a lightning-shaped pattern or a tuning fork or inverted tuning fork-shaped pattern shape, the pattern may not be accurately reproduced during device manufacture and, thus, may be undesirable in a device layout.

In view of the above considerations, some possible positions for the CM0 patterns on the peripheral M0 tracks LA1 and LA3 are not used to implement M0 gaps. Particularly, CM0 positions that are within 1.5 CPP of a vertical cell boundary are not used to form M0 gaps in the peripheral M0 tracks LA1 and LA3 (in FIG. 3, reference positions 1 and 5). Further, CM0 positions that overlap an MD structure are not used to form M0 gaps in the peripheral M0 tracks LA1 and LA3 (in FIG. 3, reference positions 1, 3, and 5).

In a 3 CPP cell in another approach in which a standard cell is purely rectangular (and thus having no protrusions), the reference positions 1, 2, 4, and 5 of the second peripheral M0 track LA3 may not be used for CM0 patterns, as being within 1.5 CPP of a vertical cell boundary, and the reference positions 1, 3, and 5 of the second peripheral M0 track LA3 may not be used for CM0 patterns, as overlapping an MD structure (the same is true for the first peripheral M0 track LA1 although the reference positions are numbered from right to left; that is, the first and second peripheral M0 tracks can be viewed as being the same except for being rotated 180 degrees around a center point of the cell, such that the first and second peripheral M0 tracks have rotational symmetry). Thus, in a 3 CPP cell in the other approach, CM0 patterns may not be placed at any position of the second peripheral M0 track LA3. In the other approach, the peripheral M0 tracks are thus limited in their utility for input and/or output pins because of the lack of CM0 positions to form M0 gaps. Additionally, the M0 conductive segments formed on the peripheral M0 tracks may have longer pin lengths than desired, which can lead to undesired increases in capacitance.

In further detail, in the other approach, a CM0 pattern cannot be placed in the position of the second M0 gap 316B in FIG. 3 because such a CM0 pattern would be too close to a vertical cell boundary, e.g., within 1.5 CPP of a vertical cell boundary. Likewise, in the other approach, a CM0 pattern cannot be placed in the position of the pattern for the fifth M0 gap 316E in FIG. 3 because such a CM0 pattern would be too close to a vertical cell boundary, e.g., within 1.5 CPP of a vertical cell boundary. The first and second input pins would thus have pin lengths of 3 CPP in the other approach.

On the other hand, in the cell 301 according to some embodiments, two positions are available for forming M0 gaps. That is, reference positions 2 and 4 are available. Thus, for example, in the cell 301, a portion of boundary M0 cut on the second peripheral M0 track LA3 is moved outward so that the fifth M0 gap 316E on the reference position 4 is provided to form another M0 conductive segment section with the output pin 320 (VD pin), which has a pin length of 2 CPP. Further, the pin length of the first input pin 319A is decreased to 2 CPP (relative to a pin length of 3 CPP in the absence of the second protruding portion 310P2). These changes along the second peripheral track LA3 are likewise implemented along the first peripheral track LA1. The cell 301 according to some embodiments thus provides greater flexibility in pin placement and allows for reductions in pin lengths relative to the other approach. Further, the reductions in pin lengths reduce capacitance relative to the other approach.

In FIG. 3, a first horizontal boundary 301h1 of the cell 301 corresponds to the first power rail V01, e.g., to a middle of the first power rail V01 relative to the second direction (Y-axis direction). A second horizontal boundary 301h2 of the cell 301 is spaced apart in the second direction from the first horizontal boundary 301h1 and corresponds to the second power rail V02, e.g., to a middle of the second power rail V02 relative to the second direction. The first horizontal boundary 301h1 and the second horizontal boundary 301h2 have the same length.

A first vertical boundary 301v1 of the cell 301 corresponds to the first insulating structure 328A, e.g., to a middle of the first insulating structure 328A relative to the first direction. The first vertical boundary 301v1 corresponds to a portion of the first insulating structure 328A that is overlapped by the second through fifth M0 tracks LB1, LA2, LB2, and LA3. A second vertical boundary 301v2 of the cell 301 corresponds to the second insulating structure 328B, e.g., to a middle of the second insulating structure 328B relative to the first direction. The second vertical boundary 301v2 corresponds to a portion of the second insulating structure 328B that is overlapped by the first through fourth M0 tracks LA1, LB1, LA2, and LB2. A third vertical boundary 301v3 corresponds to the first M0 gap 316A, e.g., to a middle of the first M0 gap 316A relative to the first direction. The third vertical boundary 301v3 is offset in the first direction relative to the first vertical boundary 301v1 such that the cell 301 has a first protrusion, namely the first M0 conductive segment 310A on the first peripheral M0 track LA1 has the first protruding portion 310P1 that protrudes or extends beyond the first vertical boundary 301v1. The first M0 gap 316A cuts the M0 conductor on the first peripheral track LA1 at the end of the first protruding portion 310P1. A third horizontal boundary 301h3 connects a lower end of the third vertical boundary 301v3 to an upper end of the first vertical boundary 301v1. A fourth vertical boundary 301v4 corresponds to the sixth M0 gap 316F, e.g., to a middle of the sixth M0 gap 316F relative to the first direction. The fourth vertical boundary 301v4 is offset in the first direction relative to the second vertical boundary 301v2 such that the cell 301 has a second protrusion, namely the M0 conductive segment 310B on the second peripheral M0 track LA3 has the second protruding portion 310P2 that protrudes or extends beyond the second vertical boundary 301v2. The sixth M0 gap 316F cuts the M0 conductor on the second peripheral track LA3 at the end of the second protruding portion 310P2. A fourth horizontal boundary 301h4 connects an upper end of the fourth vertical boundary 301v4 to a lower end of the second vertical boundary 301v2.

In FIG. 3, various conductive segments and corresponding M0 gaps are shown. In other embodiments, the more or fewer conductive segments and M0 gaps are formed. It will be understood that the M0 conductors can be segmented by M0 gaps to provide various intra- and inter-cell routing conductors.

In another approach in which a standard cell is purely rectangular (and thus having no protrusions), placement of cuts, e.g., M0 gaps, in peripheral regions of the cell is limited by the need to avoid forming shapes that may not be accurately reproduced during device manufacture, e.g., lightning shapes, tuning fork shapes or inverted tuning fork shapes, and the like. Thus, in the other approach, a CM0 pattern cannot be placed in the position of the second CM0 pattern (316B) in FIG. 3 because such a CM0 pattern would be too close to a vertical cell boundary, e.g., within 1.5 CPP of the vertical cell boundary. Likewise, in the other approach, a CM0 pattern cannot be placed in the position of the fifth CM0 pattern (316E) in FIG. 3 because such a CM0 pattern would be too close to a vertical cell boundary, e.g., within 1.5 CPP of the vertical cell boundary.

On the other hand, in the cell 301 in FIG. 3, the first M0 gap 316A is shifted outward in the first direction (i.e., away from the center of the cell 301) and thus the second M0 gap 316B is not within 1.5 CPP of the third vertical boundary 301v3. Likewise, the sixth M0 gap 316F is shifted outward in the first direction (i.e., away from the center of the cell 301) and thus the fifth M0 gap 316E is not within 1.5 CPP of the fourth vertical boundary 301v4. The cell 301 thus provides greater flexibility, relative to the other approach, in segmenting the peripheral M0 conductors such that greater variations are possible in the lengths of the peripheral M0 conductive segments and greater flexibility is provided in routing.

FIG. 4 is a layout diagram of an integrated circuit 400 according to some embodiments.

In FIG. 4, the integrated circuit 400 is similar to the integrated circuit 100 of FIG. 1. Elements in FIG. 4 generally correspond to elements in FIG. 1 with numbers incremented by 300.

In FIG. 4, a standard cell 401 includes recessed portions on peripheral M0 tracks LA1 and LA3, the recessed portions extending in the first direction toward the center of the cell 401. M0 conductive segments in the recessed portions are bounded by M0 gaps that are moved inward relative to another approach in which a standard cell is purely rectangular (and thus has no recesses).

In the integrated circuit 400, a boundary of the cell 401 is denoted by a dot-dash line. A first power rail V01 and a second power rail V02 are spaced apart in the second direction and provide power for the cell 401. In some embodiments, the first power rail V01 is configured to supply a first power voltage, e.g., one of VSS or VDD, and the second power rail V02 is configured to supply a second power voltage, e.g., the other of VSS or VDD. The first and second power rails V01 and V02 are in the first conductive layer, M0. The M0 layer is a conductive layer closest to the substrate and over a gate layer (or poly layer), although the present disclosure is also applicable to backside conductive layers in other embodiments.

The integrated circuit 400 includes five M0 tracks (denoted, from top to bottom in FIG. 4, as LA1, LB1, LA2, LB2, and LA3) between the first and second power rails V01 and V02. The peripheral M0 track LA1 may be referred to as a first peripheral M0 track LA1 and the peripheral M0 track LA3 may be referred to as a second peripheral M0 track.

The M0 conductors couple, among other things, four gate structures 422A, 422B, 422C, and 422D (collectively, gate structures 422). MD structures (not shown in FIG. 4) are interleaved with the gate structures 422 to correspond to source/drain regions S1 and S2. A gate structure 422 and corresponding MD structures on either side thereof are combined to form one or more transistors in the cell 401. In FIG. 4, the M0 conductors include, among other things, conductive segments for first, second, third, and fourth input pins 419A, 419B, 419C, and 419D (collectively, input pins 419) (VG pins). First input pin 419A and second input pin 419B are formed as M0 conductors along the first peripheral M0 track LA1. Third input pin 419C and fourth input pin 419D are formed as M0 conductors along the second peripheral M0 track LA3.

The gate structures 422 cross active regions (not shown in FIG. 4) that extend in the first direction. Active region interruptions are formed by a first insulating structure 428A and a second insulating structure 428B, which extend in the second direction. All of the gate structures 422 and the MD structures of the cell 401 are arranged between the first insulating structure 428A and the second insulating structure 428B. The first and second insulating structures 428A and 428B and the gate structures 422 are arranged at a regular pitch. The cell 401 is equivalent to a 5 CPP cell, i.e., the width of the cell from the first insulating structure to 428A to the second insulating structure 428B is 5 CPP.

The M0 conductors are formed to extend along the M0 tracks, and M0 gaps in the M0 conductors form a plurality of M0 conductive segments extending along the M0 tracks. In FIG. 4, the cell 401 includes six M0 gaps. A first M0 gap 416A overlaps an upper portion of the first insulating structure 428A. A second M0 gap 416B overlaps an upper portion of the second gate structure 422B. A third M0 gap 416C overlaps an upper portion of the fourth gate structure 422D. A fourth M0 gap 416D overlaps a lower portion of the second insulating structure 428B. A fifth M0 gap 416E overlaps a lower portion of the first gate structure 422A. A sixth M0 gap 416F overlaps a lower portion of the third gate structure 422C.

On the first peripheral M0 track LA1, a first conductive segment 410A extends between the first M0 gap 416A and the second M0 gap 416B, and a second M0 conductive segment 410B extends between the second M0 gap 416B and the third M0 gap 416C.

As indicated by a first arrow A01 and a first dashed box BX01 on the first peripheral M0 track LA1, the third M0 gap 416C corresponds to an upper portion of the fourth M0 gap 416D that is not formed overlapping the second insulating structure 428B at the first peripheral M0 track LA1 but instead is offset in the first direction, toward the center of the cell 401 by 1 CPP, relative to the fourth M0 gap 416D. The second M0 conductive segment 410B on the first peripheral M0 track LA1 thus has a first recessed portion 410R1.

As indicated by a second arrow A02 and a second dashed box BX02 on the second peripheral M0 track LA3, the fifth M0 gap 416E corresponds to a lower portion of the first M0 gap 416A that is not formed overlapping the first insulating structure 428A at the second peripheral M0 track LA3 but instead is offset in the first direction, toward the center of the cell 401 by 1 CPP, relative to the first M0 gap 416A. M0 conductive segment 410C on the second peripheral M0 track LA3 thus has a second recessed portion 410R2.

The third input pin 419C (VG pin), which is an M0 conductive segment on the second peripheral M0 track LA3, is bounded by the fifth M0 gap 416E and the sixth M0 gap 416F, and has a pin length of 2 CPP. The fourth input pin 419D, which is also an M0 conductive segment on the second peripheral M0 track LA3, is bounded by the sixth M0 gap 416F and the fourth M0 gap 416D, and has a pin length of 2 CPP.

As described above, some possible positions for the CM0 patterns on the peripheral M0 tracks LA1 and LA3 are not used to implement M0 cuts. Particularly, CM0 positions that are within 1.5 CPP of a vertical cell boundary are not used to form M0 gaps in the peripheral M0 tracks LA1 and LA3. Further, CM0 positions that overlap an MD structure are not used to form M0 gaps in the peripheral M0 tracks LA1 and LA3. Thus, in an approach that uses a purely rectangular standard cell (having no recesses) for a 3 CPP cell, CM0 patterns cannot be placed at any of the reference positions 1 through 5, and the input pins 419A and 419B would each have a pin length of 3 CPP, which may be longer than desired and result in increased capacitance. On the other hand, in the cell 501 according to some embodiments, a portion of boundary M0 cut on the second peripheral M0 track LA3 is moved inward. Thus, the pin length of the third input pin 419C is decreased to 2 CPP (relative to a pin length of 3 CPP in the absence of the second recessed portion 410R2). The change along the second peripheral track LA3 are likewise implemented along the first peripheral track LA1. The cell 501 according to some embodiments thus reduces some pin lengths and accordingly reduces capacitance relative to the other approach in which the cell is purely rectangular.

FIG. 5 is a layout diagram of an integrated circuit 500 according to some embodiments.

In FIG. 5, the integrated circuit 500 is similar to the integrated circuit 100 of FIG. 1. Elements in FIG. 5 generally correspond to elements in FIG. 1 with numbers incremented by 400.

In FIG. 5, a standard cell 501 includes recessed portions on peripheral M0 tracks LA1 and LA3, the recessed portions extending in the first direction toward the center of the cell 501. M0 conductive segments in the recessed portions are bounded by M0 gaps that are moved inward relative to another approach in which a standard cell is purely rectangular (and thus has no recesses).

In the integrated circuit 500, a boundary of the cell 501 is denoted by a dot-dash line. A first power rail V01 and a second power rail V02 are spaced apart in the second direction and provide power for the cell 501. In some embodiments, the first power rail V01 is configured to supply a first power voltage, e.g., one of VSS or VDD, and the second power rail V02 is configured to supply a second power voltage, e.g., the other of VSS or VDD. The first and second power rails V01 and V02 are in the first conductive layer, M0. The M0 layer is a conductive layer closest to the substrate and over a gate layer (or poly layer), although the present disclosure is also applicable to backside conductive layers in other embodiments.

The integrated circuit 500 includes five M0 tracks (denoted, from top to bottom in FIG. 5, as LA1, LB1, LA2, LB2, and LA3) between the first and second power rails V01 and V02. The peripheral M0 track LA1 may be referred to as a first peripheral M0 track LA1 and the peripheral M0 track LA3 may be referred to as a second peripheral M0 track.

The M0 conductors couple, among other things, two gate structures 522A and 522B (collectively, gate structures 522). MD structures (not shown in FIG. 5) are interleaved with the gate structures 522 to correspond to source/drain regions S1 and S2. A gate structure 522 and corresponding MD structures on either side thereof are combined to form one or more transistors in the cell 501. In FIG. 5, the M0 conductors include, among other things, M0 conductive segments for first and second input pins 519A and 519B (collectively, input pins 519) (VG pins). First input pin 519A includes a first M0 conductive segment 510A along the first peripheral M0 track LA1. Second input pin 519B includes an M0 conductive segment 510B along the second peripheral M0 track LA3.

The gate structures 522 cross active regions (not shown in FIG. 5) that extend in the first direction. Active region interruptions are formed by a first insulating structure 528A and a second insulating structure 528B, which extend in the second direction. All of the gate structures 522 and the MD structures of the cell 501 are arranged between the first insulating structure 528A and the second insulating structure 528B. The first and second insulating structures 528A and 528B and the gate structures 522 are arranged at a regular pitch. The cell 501 is equivalent to a 3 CPP cell, i.e., the width of the cell from the first insulating structure to 528A to the second insulating structure 528B is 3 CPP.

The M0 conductors are formed to extend along the M0 tracks, and M0 gaps in the M0 conductors form a plurality of M0 conductive segments extending along the M0 tracks. In FIG. 5, the cell 501 includes four M0 gaps. A first M0 gap 516A overlaps an upper portion of the first insulating structure 528A. A second M0 gap 516B overlaps an upper portion of the second gate structure 522B. A third M0 gap 516C overlaps a lower portion of the second insulating structure 528B. A fourth M0 gap 516D overlaps a lower portion of the first gate structure 522A.

On the first peripheral M0 track LA1, the first M0 conductive segment 510A extends between the first M0 gap 516A and the second M0 gap 516B.

As indicated by a first arrow A01 and a first dashed box BX01 on the first peripheral M0 track LA1, the second M0 gap 516B corresponds to an upper portion of the third M0 gap 516C that is not formed overlapping the second insulating structure 528B at the first peripheral M0 track LA1 but instead is offset in the first direction, toward the center of the cell 501 by 1 CPP, relative to the third M0 gap 516C. The first M0 conductive segment 510A on the first peripheral M0 track LA1 thus has a first recessed portion 510R1.

As indicated by a second arrow A02 and a second dashed box BX02 on the second peripheral M0 track LA3, the fourth M0 gap 516D corresponds to a lower portion of the first M0 gap 516A that is not formed overlapping the first insulating structure 528A at the second peripheral M0 track LA3 but instead is offset in the first direction, toward the center of the cell 501 by 1 CPP, relative to the first M0 gap 516A. The M0 conductive segment 510B on the second peripheral M0 track LA3 thus has a second recessed portion 510R2.

The second input pin 519B (VG pin), which is an M0 conductive segment on the second peripheral M0 track LA3, is bounded by the fourth M0 gap 516D and the third M0 gap 516C, and has a pin length of 2 CPP. Recessing the M0 conductor on the second peripheral M0 track LA3 reduces the pin length of the second input pin 519B from 3 CPP to 2 CPP, thus advantageously reducing capacitance of the second input pin 519B relative to another approach in which a cell is purely rectangular (and thus has no recesses).

In FIG. 5, reference CM0 positions 1 through 5 for the second peripheral M0 track LA3 are identified below the cell 501. The reference CM0 positions 1 through 5 represent possible locations along the second peripheral M0 track LA3 that may be considered for forming M0 gaps. Although some aspects of the following description relate to the placement of CM0 patterns and/or M0 gaps along positions of the second peripheral M0 track LA3, such descriptions also apply to the first peripheral track LA1 in FIG. 5 except for being rotated 180 degrees around a center point of the cell, such that the first and second peripheral M0 tracks have rotational symmetry.

As described above, some possible positions for the CM0 patterns on the peripheral M0 tracks LA1 and LA3 are not used to implement M0 cuts. Particularly, CM0 positions that are within 1.5 CPP of a vertical cell boundary are not used to form M0 gaps in the peripheral M0 tracks LA1 and LA3. Further, CM0 positions that overlap an MD structure are not used to form M0 gaps in the peripheral M0 tracks LA1 and LA3. Thus, in an approach that uses a purely rectangular standard cell (having no recesses) for a 3 CPP cell, CM0 patterns cannot be placed at any of the reference positions 1 through 5, and the input pins 519A and 519B would each have a pin length of 3 CPP, which may be longer than desired and result in increased capacitance. On the other hand, in the cell 501 according to some embodiments, a portion of boundary M0 cut on the second peripheral M0 track LA3 is moved inward. Thus, the pin length of the second input pin 519B is decreased to 2 CPP (relative to a pin length of 3 CPP in the absence of the second recessed portion 510R2). The change along the second peripheral track LA3 are likewise implemented along the first peripheral track LA1. The cell 501 according to some embodiments thus reduces some pin lengths and accordingly reduces capacitance relative to the other approach in which the cell is purely rectangular.

FIG. 6 is a layout diagram of an integrated circuit 600 according to some embodiments.

In FIG. 6, the integrated circuit 600 is similar to the integrated circuit 100 of FIG. 1. Elements in FIG. 6 generally correspond to elements in FIG. 1 with numbers incremented by 500.

In FIG. 6, a standard cell 601 includes a protruding portion on first peripheral M0 track LA1 and a recessed portion on second peripheral track LA3. The protruding portion extends in the first direction away from the center of the cell 601. The recessed portion extends in the first direction toward the center of the cell 601. An M0 conductive segment in the protruding portion is bounded by a M0 gap that is moved outward relative to another approach in which a standard cell is purely rectangular (and thus has no protrusions or recesses). An M0 conductive segment in the recessed portion is bounded by a M0 gap that is moved inward relative to the other approach in which the standard cell is purely rectangular.

In the integrated circuit 600, a boundary of the cell 601 is denoted by a dot-dash line. A first power rail V01 and a second power rail V02 are spaced apart in the second direction and provide power for the cell 601. In some embodiments, the first power rail V01 is configured to supply a first power voltage, e.g., one of VSS or VDD, and the second power rail V02 is configured to supply a second power voltage, e.g., the other of VSS or VDD. The first and second power rails V01 and V02 are in the first conductive layer, M0. The M0 layer is a conductive layer closest to the substrate and over a gate layer (or poly layer), although the present disclosure is also applicable to backside conductive layers in other embodiments.

The integrated circuit 600 includes five M0 tracks (denoted, from top to bottom in FIG. 6, as LA1, LB1, LA2, LB2, and LA3) between the first and second power rails V01 and V02. The peripheral M0 track LA1 may be referred to as a first peripheral M0 track LA1 and the peripheral M0 track LA3 may be referred to as a second peripheral M0 track.

The M0 conductors couple, among other things, first, second, third, and fourth gate structures 622A, 622B, 622C, and 622D (collectively, gate structures 622). MD structures (not shown in FIG. 6) are interleaved with the gate structures 622 to correspond to source/drain regions S1 and S2. A gate structure 622 and corresponding MD structures on either side thereof are combined to form one or more transistors in the cell 601. In FIG. 6, the M0 conductors include, among other things, conductive segments for first, second, third, and fourth input pins 619A, 619B, 619C, and 619D (collectively, input pins 619) (VG pins). First input pin 619A and second input pin 619B are formed as M0 conductors along the first peripheral M0 track LA1. Third input pin 619C and fourth input pin 619D are formed as M0 conductors along the second peripheral M0 track LA3.

The gate structures 622 cross active regions (not shown in FIG. 6) that extend in the first direction. Active region interruptions are formed by a first insulating structure 628A and a second insulating structure 628B, which extend in the second direction. All of the gate structures 622 and the MD structures of the cell 601 are arranged between the first insulating structure 628A and the second insulating structure 628B. The first and second insulating structures 628A and 628B and the gate structures 622 are arranged at a regular pitch. The cell 601 is equivalent to a 5 CPP cell, i.e., the width of the cell from the first insulating structure to 628A to the second insulating structure 628B is 5 CPP.

The M0 conductors are formed to extend along the M0 tracks, and M0 gaps in the M0 conductors form a plurality of M0 conductive segments extending along the M0 tracks. In FIG. 6, the cell 601 includes seven M0 gaps. A first M0 gap 616A defines an end of a protruding portion of a first M0 conductive segment 610A on the first peripheral M0 track LA1. A second M0 gap 616B overlaps an upper portion of the first gate structure 622A. A third M0 gap 616C overlaps an upper portion of the third gate structure 622C. A fourth M0 gap 616D overlaps an upper portion of the second insulating structure 628B. A fifth M0 gap 616E overlaps a lower portion of the first insulating structure 628A. A sixth M0 gap 616F overlaps a lower portion of the second gate structure 622B. A seventh M0 gap 616G overlaps a lower portion of the fourth gate structure 622D.

On the first peripheral M0 track LA1, the first M0 conductive segment 610A extends between the first M0 gap 616A and the second M0 gap 616B.

As indicated by a first arrow A01 and a first dashed box BX01 on the first peripheral M0 track LA1, the first M0 gap 616A corresponds to an upper portion of the fifth M0 gap 616E that is not formed overlapping the first insulating structure 628A at the first peripheral M0 track LA1 but instead is offset in the first direction, away from the center of the cell 601 by 1 CPP, relative to the fifth M0 gap 616E. The first M0 conductive segment 610A on the first peripheral M0 track LA1 thus has a protruding portion 610P1.

As indicated by a second arrow A02 and a second dashed box BX02 on the second peripheral M0 track LA3, the seventh M0 gap 616G corresponds to a lower portion of the fourth M0 gap 616D that is not formed overlapping the second insulating structure 628B at the second peripheral M0 track LA3 but instead is offset in the first direction, toward the center of the cell 601 by 1 CPP, relative to the fourth M0 gap 616D. M0 conductive segment 610B on the second peripheral M0 track LA3 thus has a recessed portion 610R1. The seventh M0 gap 616G is shared by the cell 601 and a right-hand side cell abutted horizontally to the cell 601.

On the first M0 peripheral track LA1, moving the first M0 gap outward allows the second M0 gap 616B to be placed without being within 1.5 CPP of a vertical cell boundary. The second M0 gap 616B shortens the first input pin 619A to 2 CPP, thus reducing capacitance of the first input pin 619A relative to an input pin of 3 CPP (the distance between the fifth M0 gap 616E (if extended over the first peripheral M0 track LA1) and the third M0 gap 616C on the first peripheral M0 track LA1). Further, in some embodiments, an output pin (VD) (not shown in FIG. 6) is positioned on the first peripheral M0 track LA1 on the MD structure between the first insulating structure 628A and the first gate structure 622A, which enables additional routing flexibility (the output pin (VD) would extend between the first M0 gap 616A and the second M0 gap 616B, with a pin length of 2 CPP).

The third input pin 619C (VG pin), which is an M0 conductive segment on the second peripheral M0 track LA3, is bounded by the fifth M0 gap 616E and the sixth M0 gap 616F, and has a pin length of 2 CPP. The fourth input pin 619D (VG pin), which is also an M0 conductive segment on the second peripheral M0 track LA3, is bounded by the sixth M0 gap 616F and the seventh M0 gap 616G, and has a pin length of 2 CPP. Moving the seventh M0 gap 616G inward shortens the fourth input pin 619D to 2 CPP, thus reducing capacitance of the fourth input pin 619D relative to an input pin of 3 CPP (the distance between the sixth M0 gap 616F on the second peripheral M0 track LA3 and the fourth M0 gap 616D (if extended over the second peripheral M0 track LA3).

In FIG. 6, reference CM0 positions 1 through 9 for the second peripheral M0 track LA3 are identified below the cell 601. The reference CM0 positions 1 through 9 represent possible locations along the second peripheral M0 track LA3 that may be considered for forming M0 gaps.

As described above, some possible positions for the CM0 patterns on the peripheral M0 tracks LA1 and LA3 are not used to implement M0 gaps. Particularly, CM0 positions that are within 1.5 CPP of a vertical cell boundary are not used to form M0 gaps in the peripheral M0 tracks LA1 and LA3. Further, CM0 positions that overlap an MD structure are not used to form M0 gaps in the peripheral M0 tracks LA1 and LA3. Thus, in an approach that uses a purely rectangular standard cell (having no protrusions or recesses) for a 5 CPP cell, CM0 patterns may be placed only at the reference CM0 position 4 and the reference CM0 position 6 of the first and second peripheral M0 tracks LA1 and LA3. Thus, in the other approach, the second M0 gap 616B could not be placed over the first gate structure 622A, which would result in a pin length of 3 CPP for the first input pin 619A. On the other hand, in the embodiment of FIG. 6, the first input pin 619A has a pin length of 2 CPP, thus reducing capacitance of the first input pin 619A relative to the other approach. Further, in the embodiment of FIG. 6, the first M0 conductive segment 610A extending between the first M0 gap 616A and the second M0 gap 616B on the first peripheral M0 track LA1 is available for, e.g., an output pin (VD) having a pin length of 2 CPP. Further, in the other approach, the fourth input pin 619D would have a pin length of 3 CPP, whereas in the embodiment of FIG. 6, the fourth input pin 619D has a pin length of 2 CPP, thus reducing capacitance of the fourth input pin 619D relative to the other approach.

In FIG. 7, the integrated circuit 700 is similar to the integrated circuit 100 of FIG. 1. Elements in FIG. 7 generally correspond to elements in FIG. 1 with numbers incremented by 600.

In FIG. 7, a standard cell 701 includes a recessed portion on first peripheral M0 track LA1 and a protruding portion on second peripheral track LA3. The recessed portion extends in the first direction toward the center of the cell 701. The protruding portion extends in the first direction away from the center of the cell 701. An M0 conductive segment in the recessed portion is bounded by a M0 gap that is moved inward relative to another approach in which a standard cell is purely rectangular (and thus has no protrusions or recesses). An M0 conductive segment in the protruding portion is bounded by a M0 gap that is moved outward relative to the other approach in which the standard cell is purely rectangular.

In the integrated circuit 700, a boundary of the cell 701 is denoted by a dot-dash line. A first power rail V01 and a second power rail V02 are spaced apart in the second direction and provide power for the cell 701. In some embodiments, the first power rail V01 is configured to supply a first power voltage, e.g., one of VSS or VDD, and the second power rail V02 is configured to supply a second power voltage, e.g., the other of VSS or VDD. The first and second power rails V01 and V02 are in the first conductive layer, M0. The M0 layer is a conductive layer closest to the substrate and over a gate layer (or poly layer), although the present disclosure is also applicable to backside conductive layers in other embodiments.

The integrated circuit 700 includes five M0 tracks (denoted, from top to bottom in FIG. 7, as LA1, LB1, LA2, LB2, and LA3) between the first and second power rails V01 and V02. The peripheral M0 track LA1 may be referred to as a first peripheral M0 track LA1 and the peripheral M0 track LA3 may be referred to as a second peripheral M0 track.

The M0 conductors couple, among other things, first and second gate structures 722A and 722B (collectively, gate structures 722). MD structures (not shown in FIG. 7) are interleaved with the gate structures 722 to correspond to source/drain regions S1 and S2. A gate structure 722 and corresponding MD structures on either side thereof are combined to form one or more transistors in the cell 701. In FIG. 7, the M0 conductors include, among other things, conductive segments for first and second input pins 719A and 719B (collectively, input pins 719) (VG pins). The first input pin 719A includes an M0 conductive segment 710A along the first peripheral M0 track LA1. The second input pin 719B includes an M0 conductive segment 710B along the second peripheral M0 track LA3.

The gate structures 722 cross active regions (not shown in FIG. 7) that extend in the first direction. Active region interruptions are formed by a first insulating structure 728A and a second insulating structure 728B, which extend in the second direction. All of the gate structures 722 and the MD structures of the cell 701 are arranged between the first insulating structure 728A and the second insulating structure 728B. The first and second insulating structures 728A and 728B and the gate structures 722 are arranged at a regular pitch. The cell 701 is equivalent to a 3 CPP cell, i.e., the width of the cell from the first insulating structure to 728A to the second insulating structure 728B is 3 CPP.

The M0 conductors are formed to extend along the M0 tracks, and M0 gaps in the M0 conductors form a plurality of M0 conductive segments extending along the M0 tracks. In FIG. 7, the cell 701 includes five M0 gaps. A first M0 gap 716A overlaps an upper portion of the first gate structure 722A. A second M0 gap 716B overlaps an upper portion of the second insulating structure 728B. A third M0 gap 716C overlaps a lower portion of the first insulating structure 728A. A fourth M0 gap 716D overlaps a lower portion of the second gate structure 722B. A fifth M0 gap 716E defines an end of a protruding portion of an M0 conductor on the second peripheral M0 track LA3.

On the second peripheral M0 track LA3, the M0 conductive segment 710B extends between the fourth M0 gap 716D and the fifth M0 gap 716E, and protrudes beyond the second insulating structure 728B in the first direction away from the center of the cell 701.

As indicated by a first arrow A01 and a first dashed box BX01 on the first peripheral M0 track LA1, the first M0 gap 716A corresponds to an upper portion of the third M0 gap 716C that is not formed overlapping the first insulating structure 728A at the first peripheral M0 track LA1 but instead is offset in the first direction, toward the center of the cell 701 by 1 CPP, relative to the third M0 gap 716C. The M0 conductive segment 710B on the first peripheral M0 track LA1 thus has a recessed portion 710R1.

As indicated by a second arrow A02 and a second dashed box BX02 on the second peripheral M0 track LA3, the fifth M0 gap 716E corresponds to a lower portion of the second M0 gap 716B that is not formed overlapping the second insulating structure 728B at the second peripheral M0 track LA3 but instead is offset in the first direction, away from the center of the cell 701 by 1 CPP, relative to the second M0 gap 716B. The M0 conductive segment 710B on the second peripheral M0 track LA3 thus has a protruding portion 710P1.

Regarding the recessed portion of the cell along the first peripheral M0 track LA1, the first input pin 719A (VG pin), which includes the M0 conductive segment 710A on the first peripheral M0 track LA1, is bounded by the first M0 gap 716A and the second M0 gap 716B, and has a pin length of 2 CPP. Moving the first M0 gap 716A inward shortens the first input pin 719A to 2 CPP, thus reducing capacitance of the first input pin 719A relative to an input pin of 3 CPP (the distance between the third M0 gap 716C (if extended over the first peripheral M0 track LA1) and the second M0 gap 716B on the first peripheral M0 track LA1.

On the second M0 peripheral track LA3, moving the fifth M0 gap 716E outward allows the fourth M0 gap 716D to be placed to overlap the second gate structure 722B over the second M0 peripheral track LA3, without being within 1.5 CPP of a vertical cell boundary. The fourth M0 gap 716D shortens the length of the second input pin 719B to 2 CPP, thus reducing capacitance of the second input pin 719B relative to an input pin of 3 CPP (the distance between the third M0 gap 716C on the second peripheral M0 track LA3 and the second M0 gap 716B (if extended over the second peripheral M0 track LA3). Further, in some embodiments, an output pin (VD) (not shown in FIG. 7) is positioned on the second peripheral M0 track LA3 on the MD structure between the second gate structure 722B and the second insulating structure 728B, which enables additional routing flexibility (the output pin (VD) would extend between the fourth M0 gap 716D and the fifth M0 gap 716E, with a pin length of 2 CPP).

In FIG. 7, reference CM0 positions 1 through 5 for the second peripheral M0 track LA3 are identified below the cell 701. The reference CM0 positions 1 through 5 represent possible locations along the second peripheral M0 track LA3 that may be considered for forming M0 gaps.

As described above, some possible positions for the CM0 patterns on the peripheral M0 tracks LA1 and LA3 are not used to implement M0 gaps. Particularly, CM0 positions that are within 1.5 CPP of a vertical cell boundary are not used to form M0 gaps in the peripheral M0 tracks LA1 and LA3. Further, CM0 positions that overlap an MD structure are not used to form M0 gaps in the peripheral M0 tracks LA1 and LA3. Thus, in an approach that uses a purely rectangular standard cell (having no protrusions or recesses) for a 3 CPP cell, CM0 patterns may not be placed at any of the reference CM0 positions of the second peripheral M0 track LA3. Thus, in the other approach, the first M0 gap 716A could not be placed over the first gate structure 722A, which would result in a pin length of 3 CPP for the first input pin 719A. On the other hand, in the embodiment of FIG. 7, the first input pin 719A has a pin length of 2 CPP, thus reducing capacitance of the first input pin 719A relative to the other approach. Further, in the embodiment of FIG. 7, the M0 conductive segment 710B extending between the fourth M0 gap 716D and the fifth M0 gap 716E on the second peripheral M0 track LA3 is available for, e.g., an output pin (VD) having a pin length of 2 CPP. Further, in the other approach, the second input pin 719B would have a pin length of 3 CPP, whereas in the embodiment of FIG. 7, the second input pin 719B has a pin length of 2 CPP.

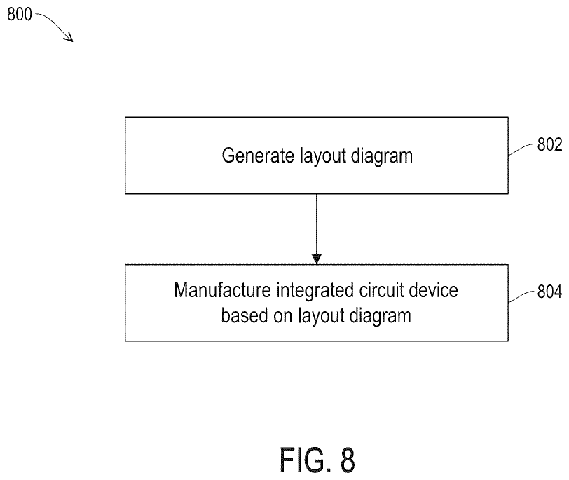

FIG. 8 is a flowchart of a method 800 of manufacturing an integrated circuit device according to some embodiments.

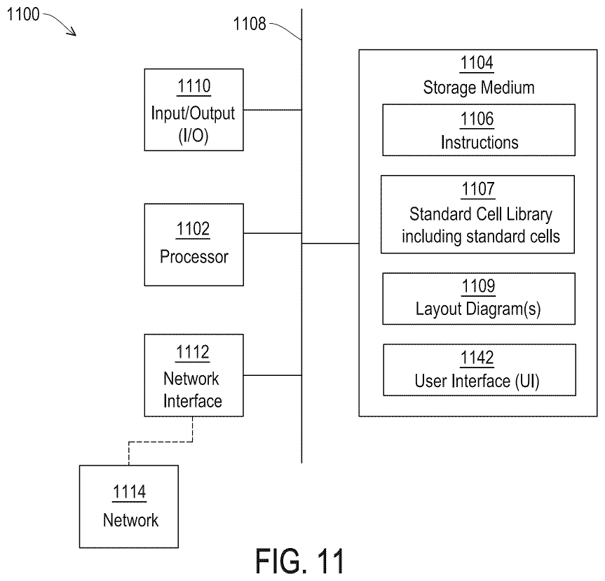

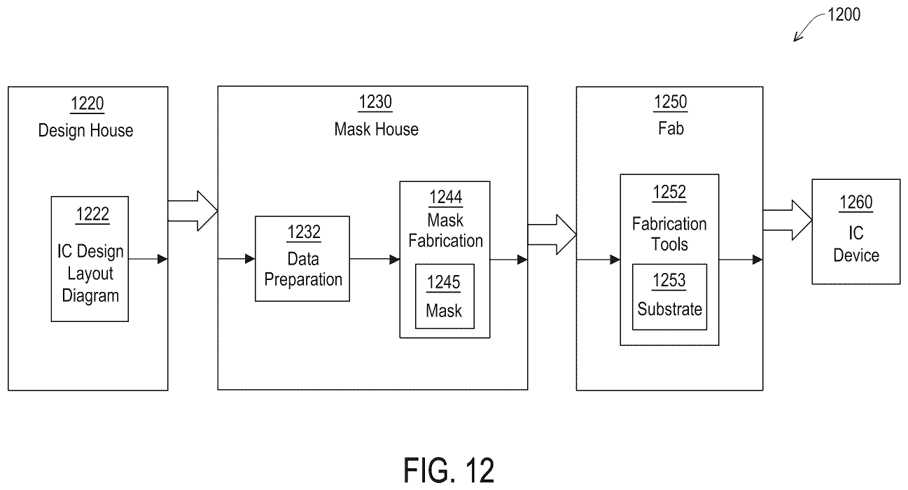

Method 800 is implementable, for example, using an electronic design automation (EDA) system 1100 (FIG. 11, discussed below) and an integrated circuit (IC) manufacturing system 1200 (FIG. 12, discussed below), according to some embodiments. Examples of an integrated circuit device that can be manufactured according to method 800 include devices corresponding to any one or more of the integrated circuits 100 through 700 described herein in connection with FIGS. 1 through 7.

Referring to FIG. 8, method 800 includes operations 802 and 804. At operation 802, a layout diagram is generated which, among other things, includes one or more of layout diagrams corresponding to integrated circuits 100 through 700 disclosed herein.

Operation 802 is implementable, for example, using the EDA system 1100 (FIG. 11, discussed below), according to some embodiments. In some embodiments, operation 802 includes generating shapes corresponding to structures that are to be represented in an integrated circuit diagram.

At operation 804, based on the layout diagram, at least one of (A) one or more photolithographic exposures are made or (B) one or more semiconductor masks are fabricated or (C) one or more components in a layer of an integrated circuit (IC) device, e.g., a semiconductor device, are fabricated. In some embodiments, operation 804 includes one or more operations described herein in connection with method 1070. See discussion below.

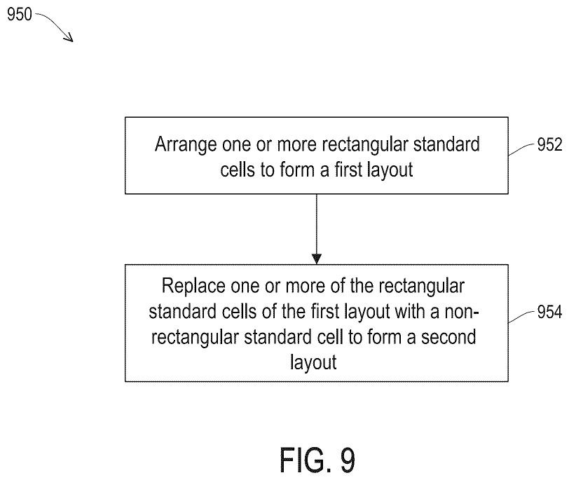

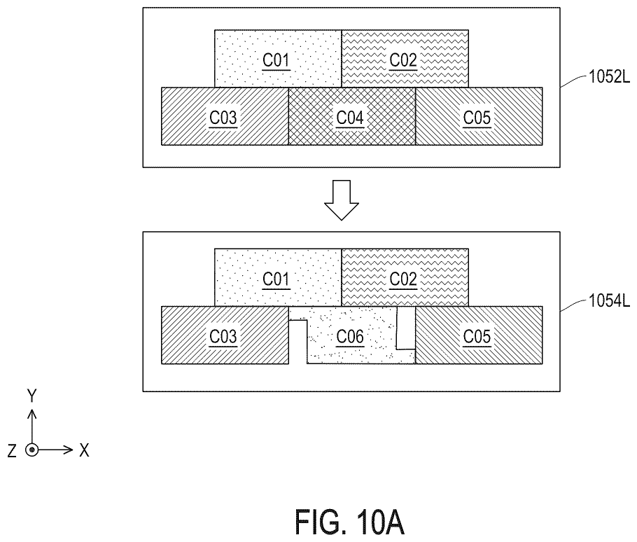

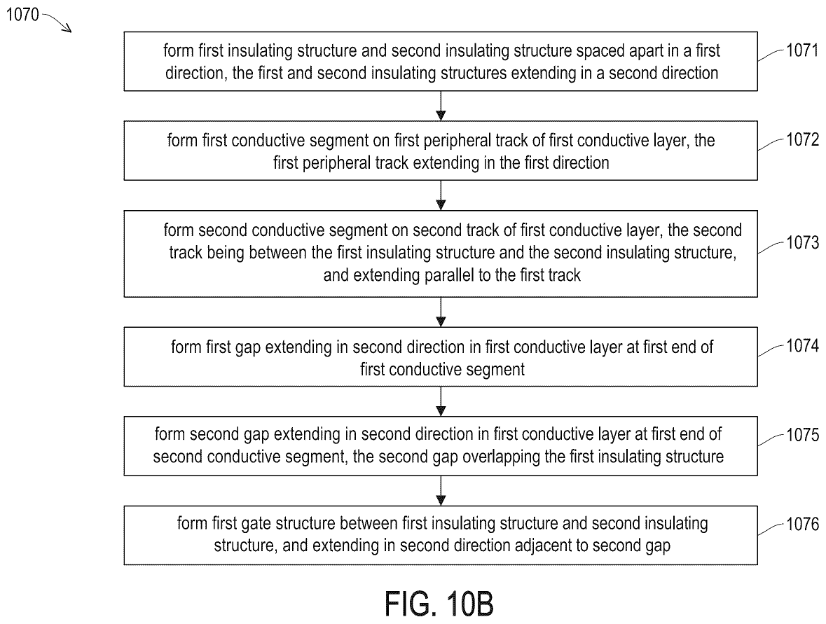

FIG. 9 is a flowchart of a method 950 of generating a layout according to some embodiments, and FIG. 10A is a schematic diagram of a method of generating a layout according to some embodiments.

In some embodiments, operation 802 of the method 800 of FIG. 8 includes the method 950 of FIG. 9.

The method 950 includes operations 952 and 954.

In operation 952, one or more purely rectangular standard cells are arranged to form a first layout. FIG. 10A schematically illustrates layout 1052L, which is an example of the first layout formed in operation 952. The layout 1052L includes first, second, third, fourth, and fifth standard cells C01, C02, C03, C04, and C05. In some embodiments, the first through fifth standard cells C01 through C05 are included in a first standard cell library. Each of the first through fifth standard cells C01 through C05 is purely rectangular, having exactly two sides that extend in the first direction and exactly two sides that extend in the second direction. Each of the first through fifth standard cells C01 through C05 is free of, i.e., does not include, a protrusion and is free of a recess.

In operation 954, one or more of the purely rectangular standard cells of the first layout is replaced with a non-rectangular standard cell to form a second layout. FIG. 10A schematically illustrates layout 1054L, which is an example of the second layout formed in operation 954. The layout 1054L includes a sixth standard cell C06, which is a non-rectangular standard cell. In some embodiments, the sixth standard cell C06 is included in the first standard cell library or in a second standard cell library. The example non-rectangular standard cell C06 in the layout 1054L has M0 conductors that have protrusions in first and second peripheral M0 tracks corresponding to the first and second peripheral M0 tracks LA1 and LA3 described above. An example of the sixth standard cell C06 in the layout 1054L is described above in connection with FIG. 2. Any of the embodiments described herein of standard cells having one or more protrusions and/or one or more recesses is usable as one or more of the non-rectangular standard cells in operation 954 and as the sixth standard cell C06 in layout 1054L. In various embodiments, one or more of the integrated circuits 100 through 700 described herein is implemented in the sixth standard cell C06. It will be understood that any one or more of the purely rectangular first, second, third, fourth, and fifth standard cells C01, C02, C03, C04, and C05 of the layout 1052L can be replaced with a non-rectangular standard cell corresponding to any one or more of the integrated circuits 100 through 700 described herein having one or more protrusions and/or one or more recesses in first and/or second peripheral M0 tracks.

FIG. 10B is a flowchart of a method 1070 of fabricating an integrated circuit device according to some embodiments.

The method 1070 includes operations 1071 through 1076.

Operation 1071 includes forming a first insulating structure and a second insulating structure spaced apart from the first insulating structure in a first direction, each of the first and second insulating structures extending in a second direction perpendicular to the first direction.

Operation 1072 includes forming a first conductive segment on a first peripheral track of a first conductive layer, the first peripheral track extending in the first direction.

Operation 1073 includes forming a second conductive segment on a second track of the first conductive layer, the second track being between the first insulating structure and the second insulating structure, and extending parallel to the first track.

Operation 1074 includes forming a first gap extending in the second direction in the first conductive layer at a first end of the first conductive segment.

Operation 1075 includes forming a second gap extending in the second direction in the first conductive layer at a first end of the second conductive segment, the second gap overlapping the first insulating structure.

Operation 1076 includes forming a first gate structure between the first insulating structure and the second insulating structure, and extending in the second direction adjacent to the second gap.

In some embodiments, the second gap is formed between the first gap and the first gate structure along the first direction, the first insulating structure is formed between the first gap and the first gate structure along the first direction, and the first conductive segment is formed to extend in the first direction away from the first gate structure to protrude beyond the second gap.

FIG. 11 is a block diagram of the EDA system 1100 according to some embodiments.

The EDA system 1100 is usable to design one or more of the integrated circuits 100 through 700 described herein.

In some embodiments, the EDA system 1100 includes an APR system. In some embodiments, the EDA system 1100 is or includes a general purpose computing device including a hardware processor 1102 and a non-transitory, computer-readable storage medium 1104. The storage medium 1104 is encoded with, i.e., stores, computer program code 1106, i.e., a set of executable instructions. Execution of the instructions 1106 by the processor 1102 represents (at least in part) an EDA tool which implements a portion or all of the methods described herein in accordance with one or more embodiments (hereinafter, the noted processes and/or methods).

In some embodiments, methods described herein of designing layout diagrams representing wire routing arrangements are implementable using the EDA system 1100.

In some embodiments, the EDA system 1100 is configured to perform an APR operation to generate a layout of an IC, e.g., based on a schematic of the IC, the APR operation including a cell placement operation that places a first cell and a second cell in the layout diagram such that the first and second cells adjoin one another at a cell boundary, and a routing operation that routes a net interconnecting the first and second cells in the layout diagram, the routing operation including: routing a first conductive layer such that: a first conductor in the first cell is coupled to a gate of a first transistor in the first cell; routing a second conductive layer, which is higher than the first conductive layer, such that: a second conductor is in the second cell and adjoins the cell boundary, a pin conductor is in the first cell and adjoins the cell boundary, and the second conductor extends in the second cell and is coupled between a source/drain region of a second transistor in the second cell and the pin conductor; and routing a third conductive layer, which is higher than the second conductive layer, such that: a third conductor is in the first cell and forms at least a portion of a conductive path in the first cell between the first conductor and the second conductor, the third conductor being spaced apart from the cell boundary, and the third conductive layer is a highest conductive layer among conductive layers forming the conductive path in the first cell.

In some embodiments, execution of the instructions 1106 by the processor 1102 represents (at least in part) an IC device design system which implements a portion or all of one or more of the noted processes and/or methods.

The processor 1102 is electrically coupled to the storage medium 1104 via a bus 1108. The processor 1102 is also electrically coupled to an I/O interface 1110 via the bus 1108. A network interface 1112 is also electrically connected to the processor 1102 via the bus 1108. The network interface 1112 is connected to a network 1114, so that the processor 1102 and the storage medium 1104 are capable of connecting to external elements via the network 1114. The processor 1102 is configured to execute the instructions 1106 encoded in the storage medium 1104 in order to cause the EDA system 1100 to be usable for performing a portion or all of the noted processes and/or methods. In one or more embodiments, the processor 1102 is a central processing unit (CPU), a multi-processor, a distributed processing system, an application specific integrated circuit (ASIC), and/or a suitable processing unit.

In one or more embodiments, the storage medium 1104 is an electronic, magnetic, optical, electromagnetic, infrared, and/or a semiconductor system (or apparatus or device). In one or more embodiments, the storage medium 1104 includes a semiconductor or solid-state memory, a magnetic tape, a removable computer diskette, a random-access memory (RAM), a read-only memory (ROM), a rigid magnetic disk, and/or an optical disk. In one or more embodiments using optical disks, the storage medium 1104 includes a compact disc read-only memory (CD-ROM), a compact disc-read/write (CD-R/W), and/or a digital video disc (DVD).

In one or more embodiments, the storage medium 1104 stores the instructions 1106 configured to cause the EDA system 1100 (where such execution represents (at least in part) the EDA tool) to be usable for performing a portion or all of the noted processes and/or methods. In one or more embodiments, the storage medium 1104 also stores information that facilitates performing a portion or all of the noted processes and/or methods. In one or more embodiments, the storage medium 1104 stores a library 1107 of standard cells including such standard cells as disclosed herein. In one or more embodiments, the storage medium 1104 stores one or more layout diagrams 1109 corresponding to one or more layouts disclosed herein.

The EDA system 1100 includes the I/O interface 1110. The I/O interface 1110 is coupled to external circuitry. In one or more embodiments, the I/O interface 1110 includes a keyboard, keypad, mouse, trackball, trackpad, touchscreen, and/or cursor direction keys for communicating information and commands to the processor 1102.

The EDA system 1100 also includes the network interface 1112 coupled to the processor 1102. The network interface 1112 allows the EDA system 1100 to communicate with the network 1114, to which one or more other computer systems are connected. The network interface 1112 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1100.

The EDA system 1100 is configured to receive information through the I/O interface 1110. The information received through the I/O interface 1110 includes one or more of instructions, data, design rules, libraries of standard cells, and/or other parameters for processing by the processor 1102. The information is transferred to the processor 1102 via the bus 1108. The EDA system 1100 is configured to receive information related to a user interface (UI) through the I/O interface 1110. The information is stored in the storage medium 1104 as a user interface (UI) 1142.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by the EDA system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 12 is a block diagram of the IC manufacturing system 1200, and an IC manufacturing flow associated therewith according to some embodiments. In some embodiments, based on a layout diagram, e.g., corresponding to one or more of the integrated circuits 100 through 700 described herein, at least one of (A) one or more semiconductor masks or (B) at least one component in a layer of a semiconductor integrated circuit is fabricated using the IC manufacturing system 1200.

In FIG. 12, the IC manufacturing system 1200 includes entities, such as a design house 1220, a mask house 1230, and an IC manufacturer/fabricator (“fab”) 1250, that interact with one another in the design, development, and manufacturing cycles and/or services related to manufacturing an IC device 1260. The entities in the IC manufacturing system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1220, the mask house 1230, and the IC fab 1250 is owned by a single larger company. In some embodiments, two or more of the design house 1220, the mask house 1230, and the IC fab 1250 coexist in a common facility and use common resources.

The design house (or design team) 1220 generates an IC design layout diagram 1222 based on the noted processes and/or methods discussed above. The IC design layout diagram 1222 includes various geometrical patterns that correspond to patterns of metal, oxide, or semiconductor layers that make up the various components of the IC device 1260 to be fabricated. The various layers combine to form various IC features. For example, a portion of the IC design layout diagram 1222 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 1220 implements a proper design procedure to form the IC design layout diagram 1222. The design procedure includes one or more of logic design, physical design or place and route. The IC design layout diagram 1222 is presented in one or more data files having information of the geometrical patterns. For example, the IC design layout diagram 1222 can be expressed in a GDSII file format or DFII file format.

The mask house 1230 includes mask data preparation 1232 and mask fabrication 1244. The mask house 1230 uses the IC design layout diagram 1222 to manufacture one or more masks 1245 to be used for fabricating the various layers of the IC device 1260 according to the IC design layout diagram 1222. The mask house 1230 performs the mask data preparation 1232, where the IC design layout diagram 1222 is translated into a representative data file (RDF). The mask data preparation 1232 provides the RDF to the mask fabrication 1244. The mask fabrication 1244 includes a mask writer. A mask writer converts the RDF to an image on a substrate, such as a mask (reticle) 1245 or a substrate 1253, e.g., a semiconductor wafer. The IC design layout diagram 1222 is manipulated by the mask data preparation 1232 to comply with particular characteristics of the mask writer and/or requirements of the IC fab 1250. In FIG. 12, the mask data preparation 1232 and the mask fabrication 1244 are illustrated as separate elements. In some embodiments, the mask data preparation 1232 and the mask fabrication 1244 can be collectively referred to as mask data preparation.

In some embodiments, the mask data preparation 1232 includes optical proximity correction (OPC) which uses lithography enhancement techniques to compensate for image errors, such as those that can arise from diffraction, interference, other process effects and the like. OPC adjusts the IC design layout diagram 1222. In some embodiments, the mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1232 includes a mask rule checker (MRC) that checks the IC design layout diagram 1222 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1222 to compensate for limitations during the mask fabrication 1244, which may undo part of the modifications performed by OPC in order to meet mask creation rules.

In some embodiments, the mask data preparation 1232 includes lithography process checking (LPC) that simulates processing that will be implemented by the IC fab 1250 to fabricate the IC device 1260. LPC simulates this processing based on the IC design layout diagram 1222 to create a simulated manufactured device, such as the IC device 1260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine the IC design layout diagram 1222.

It should be understood that the above description of the mask data preparation 1232 has been simplified for the purposes of clarity. In some embodiments, the mask data preparation 1232 includes additional features such as a logic operation (LOP) to modify the IC design layout diagram 1222 according to manufacturing rules. Additionally, the processes applied to the IC design layout diagram 1222 during the mask data preparation 1232 may be executed in a variety of different orders.

After the mask data preparation 1232 and during the mask fabrication 1244, a mask 1245 or a group of masks 1245 are fabricated based on the modified IC design layout diagram 1222. In some embodiments, the mask fabrication 1244 includes performing one or more lithographic exposures based on the IC design layout diagram 1222. In some embodiments, an electron-beam (e-beam) or a mechanism of multiple e-beams is used to form a pattern on a mask (photomask or reticle) 1245 based on the modified IC design layout diagram 1222. The mask 1245 can be formed in various technologies. In some embodiments, the mask 1245 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 1245 includes a transparent substrate (e.g., fused quartz) and an opaque material (e.g., chromium) coated in the opaque regions of the binary mask. In another example, the mask 1245 is formed using a phase shift technology. In a phase shift mask (PSM) version of the mask 1245, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1244 is used in a variety of processes. For example, in some embodiments the mask(s) is used in an ion implantation process to form various doped regions in the substrate 1253, in an etching process to form various etching regions in the substrate 1253, and/or in other suitable processes.

The IC fab 1250 is an IC fabrication business that includes one or more manufacturing facilities for the fabrication of a variety of different IC products. In some embodiments, the IC fab 1250 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1250 includes wafer fabrication tools 1252 configured to execute various manufacturing operations on the substrate 1253 such that the IC device 1260 is fabricated in accordance with the mask(s), e.g., the mask 1245. In some embodiments, the wafer fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1250 uses mask(s) 1245 fabricated by the mask house 1230 to fabricate the IC device 1260. Thus, the IC fab 1250 at least indirectly uses the IC design layout diagram 1222 to fabricate the IC device 1260. In some embodiments, the substrate 1253 is fabricated by the IC fab 1250 using mask(s) 1245 to form the IC device 1260. In some embodiments, the IC fabrication includes performing one or more lithographic exposures based at least indirectly on the IC design layout diagram 1222. In some embodiments, the substrate 1253 includes a silicon substrate or other proper substrate having material layers formed thereon. In some embodiments, the substrate 1253 further includes one or more of various doped regions, dielectric features, multilevel interconnects, and the like (formed at subsequent manufacturing steps).

Details regarding an IC manufacturing system (e.g., IC manufacturing system 1200 of FIG. 12), and an IC manufacturing flow associated therewith are found, e.g., in U.S. Pat. No. 9,256,709, granted Feb. 9, 2016, U.S. Pre-Grant Publication No. 2015/0278429 A1, published Oct. 1, 2015, U.S. Pre-Grant Publication No. 2014/0040838 A1, published Feb. 6, 2014, and U.S. Pat. No. 7,260,442, granted Aug. 21, 2007, the entireties of each of which are hereby incorporated by reference.

In some embodiments, a semiconductor device includes: a first metal layer extending along a first direction, wherein the first metal layer is divided into a plurality of first metal sections by a plurality of isolation areas, the isolation areas including: a plurality of first isolation areas on boundaries of the semiconductor device; and a plurality of second isolation areas between the boundaries of the semiconductor device, wherein the second isolation areas are shorter than the first isolation areas; and a plurality of gate structures extending along a second direction (vertical direction) perpendicular to the first direction, the second isolation areas overlapping with the gate structures from a top view of the semiconductor device, and at least one of the second isolation areas being formed by shifting a portion of the first isolation area along the first direction. In some embodiments, each of the first metal sections is provided with a first pin or a second pin. In some embodiments, a length of each of the first metal sections is twice of a distance between two adjacent ones of the gate structures.

In some embodiments, an integrated circuit device includes: a first conductive segment on a first track of a first conductive layer, the first track extending in a first direction; a second conductive segment on the first track; a third conductive segment on a second track of the first conductive layer, the second track extending parallel to the first track; a fourth conductive segment on a third track of the first conductive layer, the third track extending parallel to the first track; a first gap in the first conductive layer at a first end of the first conductive segment; a second gap in the first conductive layer at a second end of the first conductive segment and a first end of the second conductive segment, the second gap separating the second end of the first conductive segment from the first end of the second conductive segment; a third gap extending in a second direction, perpendicular to the first direction, in the first conductive layer at first ends of the third and fourth conductive segments, the third gap being between the first gap and the second gap along the first direction; a first via structure between the third gap and the second gap along the first direction, the first via structure connecting the first conductive segment and a first MD structure together; and a first gate structure adjacent to the first via structure, the second gap vertically overlapping the first gate structure in a third direction perpendicular to each of the first and second directions.

In some embodiments, a method of fabricating an integrated circuit device includes: forming a first conductive segment on a first track of a first conductive layer, the first track extending in a first direction; forming a second conductive segment on the first track; forming a third conductive segment on a second track of the first conductive layer, the second track extending parallel to the first track; forming a fourth conductive segment on a third track of the first conductive layer, the third track extending parallel to the first track; forming a first gap in the first conductive layer at a first end of the first conductive segment; forming a second gap in the first conductive layer at a second end of the first conductive segment and a first end of the second conductive segment, the second gap separating the second end of the first conductive segment from the first end of the second conductive segment; forming a third gap extending in a second direction, perpendicular to the first direction, in the first conductive layer at first ends of the third and fourth conductive segments, the third gap being between the first gap and the second gap along the first direction; forming a first via structure between the third gap and the second gap along the first direction, the first via structure connecting the first conductive segment and a first MD structure together; and forming a first gate structure adjacent to the first via structure, the second gap vertically overlapping the first gate structure in a third direction perpendicular to each of the first and second directions.

In some embodiments, an integrated circuit device includes: a first insulating structure and a second insulating structure spaced apart from the first insulating structure in a first direction, each of the first and second insulating structures extending in a second direction perpendicular to the first direction; a first conductive segment on a first peripheral track of a first conductive layer, the first peripheral track extending in the first direction; a second conductive segment on a second track of the first conductive layer, the second track being between the first insulating structure and the second insulating structure, and extending parallel to the first peripheral track; a first gap extending in the second direction in the first conductive layer at a first end of the first conductive segment; a second gap extending in the second direction in the first conductive layer at a first end of the second conductive segment, the second gap partially overlapping the first insulating structure; and a first gate structure between the first insulating structure and the second insulating structure, and extending in the second direction adjacent to the second gap. The second gap is between the first gap and the first gate structure along the first direction, the first insulating structure is between the first gap and the first gate structure along the first direction, and the first conductive segment extends in the first direction away from the first gate structure to protrude beyond the second gap.

In some embodiments, the integrated circuit further includes: a first power rail extending in the first direction and a second power rail extending in the first direction, the first and second power rails being spaced apart in the second direction. The first peripheral track is between the first power rail and the second track. In some embodiments, the integrated circuit device further includes: a third gap in the first conductive layer at a second end of the first conductive segment and a first end of a third conductive segment, the second gap separating the first conductive segment from the third conductive segment. The first conductive segment extends between the first gap and the third gap. In some embodiments, the third gap overlaps the first gate structure. In some embodiments, the integrated circuit device further includes: a source/drain (S/D) region between the first insulating structure and the first gate structure along the first direction; a diffusion contact structure extending in the second direction and overlapping the S/D region; and a via structure between the second gap and the third gap along the first direction, the via structure connecting the first conductive segment and the diffusion contact structure together. In some embodiments, the integrated circuit device further includes: a first diffusion contact structure extending in the second direction. The first gate structure and the first diffusion contact structure are between the first conductive layer and a substrate. In some embodiments, the integrated circuit device further includes: a third gap extending in the second direction in the first conductive layer, the third gap partially overlapping the second insulating structure. In some embodiments, the first and second insulating structures have a same first length in the second direction, the first and third gaps have a same second length in the second direction, and the first length is greater than the second length. In some embodiments, the first gap corresponds to a first part of a first vertical cell boundary, the second gap corresponds to a second part of the first vertical cell boundary, and the first vertical cell boundary is staggered. In some embodiments, the first gate structure is one of a plurality of gate structures between the first and second insulating structures, the gate structures of the plurality of gate structures being arranged along the first direction at a first gate pitch, and the first gap and the second gap are arranged along the first direction at the first gate pitch.

In some embodiments, an integrated circuit device includes: a first insulating structure and a second insulating structure spaced apart from the first insulating structure in a first direction, each of the first and second insulating structures extending in a second direction perpendicular to the first direction; a first conductive segment on a first peripheral track of a first conductive layer, the first peripheral track extending in the first direction; a second conductive segment on a second track of the first conductive layer, the second track being between the first insulating structure and the second insulating structure, and extending parallel to the first peripheral track; a first gap extending in the second direction in the first conductive layer at an end of the first conductive segment, the first gap being between the first insulating structure and the second insulating structure along the first direction; a second gap extending in the second direction in the first conductive layer at an end of the second conductive segment, the second gap partially overlapping the second insulating structure; and a first gate structure between the first insulating structure and the second insulating structure, and overlapped by the first gap. The first conductive segment is recessed in the first direction away from the second insulating structure.

In some embodiments, the integrated circuit device further includes: a first power rail extending in the first direction and a second power rail extending in the first direction, the first and second power rails being spaced apart in the second direction. The first peripheral track is between the first power rail and the second track. In some embodiments, the integrated circuit device further includes: a third conductive segment on the first peripheral track; and a third gap separating the first conductive segment from the third conductive segment. The first conductive segment extends between the first gap and the third gap. In some embodiments, the third gap overlaps a gate structure. In some embodiments, the integrated circuit device further includes: a third gap extending in the second direction in the first conductive layer, the third gap partially overlapping the first insulating structure. In some embodiments, the first and second insulating structures have a same first length in the second direction, the second and third gaps have a same second length in the second direction, and the first length is greater than the second length. In some embodiments, the first gate structure is one of a plurality of gate structures between the first and second insulating structures, the gate structures of the plurality of gate structures being arranged along the first direction at a first gate pitch, and the first gap and the second gap are arranged along the first direction at the first gate pitch.

In some embodiments, a method of manufacturing an integrated circuit device includes: arranging one or more rectangular standard cells in one or more rows to form a first layout; replacing one or more of the rectangular standard cells of the first layout with a non-rectangular standard cell to form a second layout, wherein the non-rectangular standard cell includes: a first insulating pattern and a second insulating pattern spaced apart from the first insulating pattern in a first direction, each of the first and second insulating patterns extending in a second direction perpendicular to the first direction; a first conductor pattern on a first peripheral track of a first conductive layer, the first peripheral track extending in the first direction; a second conductor pattern on a second track of the first conductive layer, the second track being between the first insulating pattern and the second insulating pattern, and extending parallel to the first peripheral track; a first cut pattern extending in the second direction in the first conductive layer at a first end of the first conductor pattern; a second cut pattern extending in the second direction in the first conductive layer at a first end of the second conductor pattern, the second cut pattern partially overlapping the first insulating pattern; and a first gate pattern between the first insulating pattern and the second insulating pattern, and extending in the second direction adjacent to the second cut pattern, wherein: the second cut pattern is between the first cut pattern and the first gate pattern along the first direction, the first insulating pattern is between the first cut pattern and the first gate pattern along the first direction, and the first conductor pattern extends in the first direction away from the first gate pattern to protrude beyond the second cut pattern; forming a first insulating structure and a second insulating structure on a substrate, the first and second insulating structures corresponding to the first and second insulating patterns; forming a first gate structure on the substrate, the first gate structure corresponding to the first gate pattern; forming a first conductor in the first conductive layer on the first peripheral track; forming a second conductor in the first conductive layer on the second track; etching the first conductor to form a first gap in the first conductor corresponding to the first cut pattern; and etching the second conductor to form a second gap in the first conductor corresponding to the second cut pattern.

In some embodiments, the non-rectangular standard cell further includes: a first power rail pattern extending in the first direction and a second power rail pattern extending in the first direction, the first and second power rail patterns being spaced apart in the second direction, wherein the first peripheral track is between the first power rail pattern and the second track. In some embodiments, the first cut pattern corresponds to a first part of a first vertical cell boundary of the non-rectangular standard cell, the second cut pattern corresponds to a second part of the first vertical cell boundary, and the first vertical cell boundary is staggered.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device comprising:
a first insulating structure and a second insulating structure spaced apart from the first insulating structure in a first direction, each of the first and second insulating structures extending in a second direction perpendicular to the first direction;
a first conductive segment on a first peripheral track of a first conductive layer, the first peripheral track extending in the first direction;
a second conductive segment on a second track of the first conductive layer, the second track being between the first insulating structure and the second insulating structure, and extending parallel to the first peripheral track;
a first gap extending in the second direction in the first conductive layer at a first end of the first conductive segment;
a second gap extending in the second direction in the first conductive layer at a first end of the second conductive segment, the second gap partially overlapping the first insulating structure; and
a first gate structure between the first insulating structure and the second insulating structure, and extending in the second direction adjacent to the second gap,
wherein:
the second gap is between the first gap and the first gate structure along the first direction,
the first insulating structure is between the first gap and the first gate structure along the first direction, and
the first conductive segment extends in the first direction away from the first gate structure to protrude beyond the second gap.

2. The integrated circuit device of claim 1, further comprising:
a first power rail extending in the first direction and a second power rail extending in the first direction, the first and second power rails being spaced apart in the second direction,
wherein the first peripheral track is between the first power rail and the second track.

3. The integrated circuit device of claim 1, further comprising:
a third gap in the first conductive layer at a second end of the first conductive segment and a first end of a third conductive segment, the second gap separating the first conductive segment from the third conductive segment,
wherein the first conductive segment extends between the first gap and the third gap.

4. The integrated circuit device of claim 3, wherein:
the third gap overlaps the first gate structure.

5. The integrated circuit device of claim 3, further comprising:
a source/drain (S/D) region between the first insulating structure and the first gate structure along the first direction;
a diffusion contact structure extending in the second direction and overlapping the S/D region; and
a via structure between the second gap and the third gap along the first direction, the via structure connecting the first conductive segment and the diffusion contact structure together.

6. The integrated circuit device of claim 1, further comprising:
a first diffusion contact structure extending in the second direction,
wherein the first gate structure and the first diffusion contact structure are between the first conductive layer and a substrate.

7. The integrated circuit device of claim 1, further comprising:
a third gap extending in the second direction in the first conductive layer, the third gap partially overlapping the second insulating structure.

8. The integrated circuit device of claim 7, wherein:
the first and second insulating structures have a same first length in the second direction,
the first and third gaps have a same second length in the second direction, and
the first length is greater than the second length.

9. The integrated circuit device of claim 1, wherein:
the first gap corresponds to a first part of a first vertical cell boundary,
the second gap corresponds to a second part of the first vertical cell boundary, and
the first vertical cell boundary is staggered.

10. The integrated circuit device of claim 1, wherein:
the first gate structure is one of a plurality of gate structures between the first and second insulating structures, the gate structures of the plurality of gate structures being arranged along the first direction at a first gate pitch, and
the first gap and the second gap are arranged along the first direction at the first gate pitch.

11. An integrated circuit device comprising:
a first insulating structure and a second insulating structure spaced apart from the first insulating structure in a first direction, each of the first and second insulating structures extending in a second direction perpendicular to the first direction;
a first conductive segment on a first peripheral track of a first conductive layer, the first peripheral track extending in the first direction;
a second conductive segment on a second track of the first conductive layer, the second track being between the first insulating structure and the second insulating structure, and extending parallel to the first peripheral track;
a first gap extending in the second direction in the first conductive layer at an end of the first conductive segment, the first gap being between the first insulating structure and the second insulating structure along the first direction;
a second gap extending in the second direction in the first conductive layer at an end of the second conductive segment, the second gap partially overlapping the second insulating structure; and
a first gate structure between the first insulating structure and the second insulating structure, and overlapped by the first gap,
wherein:
the first conductive segment is recessed in the first direction away from the second insulating structure.

12. The integrated circuit device of claim 11, further comprising:
a first power rail extending in the first direction and a second power rail extending in the first direction, the first and second power rails being spaced apart in the second direction,
wherein the first peripheral track is between the first power rail and the second track.

13. The integrated circuit device of claim 11, further comprising:
a third conductive segment on the first peripheral track; and
a third gap separating the first conductive segment from the third conductive segment,
wherein the first conductive segment extends between the first gap and the third gap.

14. The integrated circuit device of claim 13, wherein:
the third gap overlaps a gate structure.

15. The integrated circuit device of claim 11, further comprising:
a third gap extending in the second direction in the first conductive layer, the third gap partially overlapping the first insulating structure.

16. The integrated circuit device of claim 15, wherein:
the first and second insulating structures have a same first length in the second direction,
the second and third gaps have a same second length in the second direction, and
the first length is greater than the second length.

17. The integrated circuit device of claim 11, wherein:
the first gate structure is one of a plurality of gate structures between the first and second insulating structures, the gate structures of the plurality of gate structures being arranged along the first direction at a first gate pitch, and
the first gap and the second gap are arranged along the first direction at the first gate pitch.

18. A method of manufacturing an integrated circuit device, the method comprising:
arranging one or more rectangular standard cells in one or more rows to form a first layout;
replacing one or more of the rectangular standard cells of the first layout with a non-rectangular standard cell to form a second layout, wherein the non-rectangular standard cell includes:
a first insulating pattern and a second insulating pattern spaced apart from the first insulating pattern in a first direction, each of the first and second insulating patterns extending in a second direction perpendicular to the first direction;
a first conductor pattern on a first peripheral track of a first conductive layer, the first peripheral track extending in the first direction;
a second conductor pattern on a second track of the first conductive layer, the second track being between the first insulating pattern and the second insulating pattern, and extending parallel to the first peripheral track;
a first cut pattern extending in the second direction in the first conductive layer at a first end of the first conductor pattern;
a second cut pattern extending in the second direction in the first conductive layer at a first end of the second conductor pattern, the second cut pattern partially overlapping the first insulating pattern; and
a first gate pattern between the first insulating pattern and the second insulating pattern, and extending in the second direction adjacent to the second cut pattern,
wherein:
the second cut pattern is between the first cut pattern and the first gate pattern along the first direction,
the first insulating pattern is between the first cut pattern and the first gate pattern along the first direction, and
the first conductor pattern extends in the first direction away from the first gate pattern to protrude beyond the second cut pattern;
forming a first insulating structure and a second insulating structure on a substrate, the first and second insulating structures corresponding to the first and second insulating patterns;
forming a first gate structure on the substrate, the first gate structure corresponding to the first gate pattern;
forming a first conductor in the first conductive layer on the first peripheral track;
forming a second conductor in the first conductive layer on the second track;
etching the first conductor to form a first gap in the first conductor corresponding to the first cut pattern; and
etching the second conductor to form a second gap in the first conductor corresponding to the second cut pattern.

19. The method of claim 18, wherein the non-rectangular standard cell further includes:
a first power rail pattern extending in the first direction and a second power rail pattern extending in the first direction, the first and second power rail patterns being spaced apart in the second direction,
wherein the first peripheral track is between the first power rail pattern and the second track.

20. The method of claim 18, wherein:
the first cut pattern corresponds to a first part of a first vertical cell boundary of the non-rectangular standard cell,
the second cut pattern corresponds to a second part of the first vertical cell boundary, and
the first vertical cell boundary is staggered.
